(19) United States
(12) Patent Application Publication
(10) Pub. No.: US 2025/0221196 A1
(43) Pub. Date: Jul. 3, 2025

(54) Display Device

(71) Applicant: LG Display Co., Ltd, Seoul (KR)

(72) Inventors: Byungjin Kim, Paju-si (KR); JungHo Bang, Paju-si (KR); Nara Shin, Seoul (KR); Harin Kim, Paju-si (KR)

(21) Appl. No.: 18/795,761

(22) Filed: Aug. 6, 2024

(30) Foreign Application Priority Data
Dec. 28, 2023 (KR) 10-2023-0195714

(51) Int. Cl. H10K 59/131; H10K 59/80

(52) U.S. Cl. CPC H10K 59/131; H10K 59/8791

(57) ABSTRACT

A display device includes a substrate including a display area and a non-display area, a semiconductor layer disposed on the substrate in the display area, a connection line disposed on the substrate in the non-display area, a gate insulating layer disposed on the semiconductor layer and the connection line; a gate line disposed on the gate insulating layer and connected to the connection line, at least one insulating layer disposed on the gate line and a light emitting element disposed on the at least one insulating layer. Herein, the connection line is made of a metal oxide and disposed on the same layer as the semiconductor layer, and the connection line between neighboring gate lines is partially removed and thus disconnected. Thus, it is possible to suppress damage to a display panel by dispersing static electricity generated during a process.

### CROSS-REFERENCE TO RELATED APPLICATION

This application claims the priority of Republic of Korea Patent Application No. 10-2023-0195714 filed on Dec. 28, 2023, in the Korean Intellectual Property Office, which is hereby incorporated by reference in its entirety.

### BACKGROUND

### Field

The present disclosure relates to a display device, and more particularly, to a display device which can suppress static electricity.

### Description of the Related Art

Currently, in a full-scale information era, a field of a display device which visually expresses electrical information signals has been rapidly developed. Also, studies are continued to improve performances of various display devices, such as reduced thickness, light weight, and low power consumption.

Typical display devices may include a liquid crystal display (LCD) device, an electro-wetting display (EWD) device, an organic light emitting display (OLED) device, and the like.

Electroluminescent display devices including OLEDs are self-emitting display devices and do not need a separate light source unlike LCDs. Thus, the electroluminescent display devices can be manufactured into a lightweight and thin form. Further, the electroluminescent display devices are advantageous in terms of power consumption since they are driven with a low voltage. Also, the electroluminescent display devices have excellent color expression ability, a high response speed, a wide viewing angle, and a high contrast ratio (CR). Therefore, the electroluminescent display devices are expected to be utilized in various fields.

### SUMMARY

An object to be achieved by the present disclosure is to provide a display device which can disperse static electricity generated during a process.

Another object to be achieved by the present disclosure is to provide a display device which can disperse static electricity and minimize or at least reduce a reflectivity of a display panel.

Yet another object to be achieved by the present disclosure is to provide a display device which can simplify a process and disperse static electricity.

Objects of the present disclosure are not limited to the above-mentioned objects, and other objects, which are not mentioned above, can be clearly understood by those skilled in the art from the following descriptions.

A display device according to an exemplary embodiment of the present disclosure includes a substrate including a display area and a non-display area, a semiconductor layer disposed on the substrate in the display area, a connection line disposed on the substrate in the non-display area, a gate insulating layer disposed on the semiconductor layer and the connection line, a gate line disposed on the gate insulating layer and connected to the connection line, at least one insulating layer disposed on the gate line and a light emitting element disposed on the at least one insulating layer. Herein, the connection line is made of a metal oxide and disposed on the same layer as the semiconductor layer, and the connection line between neighboring gate lines is partially removed and thus disconnected.

A display device according to another exemplary embodiment of the present disclosure includes a substrate including a display area and a non-display area, a gate line disposed on the substrate, a first connection line disposed in a direction crossing the gate line and connected to the gate line, an interlayer insulating layer disposed on the gate line, a second connection line disposed on the interlayer insulating layer and connected to the first connection line, at least one insulating layer disposed on the second connection line and a light emitting element disposed on the at least one insulating layer. Herein, each of the first connection line and the second connection line between neighboring gate lines is partially removed and thus disconnected.

Other detailed matters of the exemplary embodiments are included in the detailed description and the drawings.

According to an exemplary embodiment of the present disclosure, a connection line is disposed between gate lines or data lines so as to disperse static electricity. Thus, it is possible to suppress damage to a display panel. Therefore, it is possible to improve the reliability of a display device.

According to an exemplary embodiment of the present disclosure, the connection line is disposed on the same layer as a semiconductor layer under the gate lines. Therefore, static electricity can be dispersed from the formation of the gate lines to the formation of an anode.

According to an exemplary embodiment of the present disclosure, the connection line is made of a transparent metal oxide. Thus, it is possible to minimize a reflectivity of the display panel. Therefore, low power consumption can be achieved.

According to an exemplary embodiment of the present disclosure, the connection line is made of a transparent metal oxide. Thus, the connection line can be patterned when the anode is formed. Therefore, the process can be simplified.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a display device according to exemplary embodiments of the present disclosure;

FIG. 2 is a circuit diagram of a sub-pixel of the display device according to exemplary embodiments of the present disclosure;

FIG. 3 is a plan view of a display panel according to a first exemplary embodiment of the present disclosure;

FIG. 4 is an enlarged view of an area A of FIG. 3 according to an exemplary embodiment of the present disclosure;

FIG. 5 is a cross-sectional view of one sub-pixel according to an exemplary embodiment of the present disclosure;

FIG. 6 is a plan view of a part of a display panel according to a second exemplary embodiment of the present disclosure;

FIG. 7 is an enlarged view of an area B of FIG. 6 according to an exemplary embodiment of the present disclosure;

FIG. 8 is a cross-sectional view taken along a line I-I′ of FIG. 7 according to an exemplary embodiment of the present disclosure;

FIG. 9A through FIG. 9G are diagrams illustrating a process of manufacturing the display panel according to the second exemplary embodiment of the present disclosure of FIG. 7;

FIG. 10A through FIG. 10G are diagrams sequentially illustrating a process of manufacturing the display panel according to the second exemplary embodiment of the present disclosure of FIG. 8;

FIG. 11 is a plan view of a part of a display panel according to a third exemplary embodiment of the present disclosure;

FIG. 12 is an enlarged view of an area C of FIG. 11 according to an exemplary embodiment of the present disclosure;

FIG. 13A is a cross-sectional view taken along a line II-II′ of FIG. 12 according to an exemplary embodiment of the present disclosure;

FIG. 13B is a cross-sectional view taken along a line III-III′ of FIG. 12 according to an exemplary embodiment of the present disclosure;

FIG. 14A through FIG. 14F are diagrams illustrating a process of manufacturing the display panel according to the third exemplary embodiment of the present disclosure of FIG. 12;

FIG. 15A through FIG. 15F are diagrams sequentially illustrating a process of manufacturing the display panel according to the third exemplary embodiment of the present disclosure of FIG. 13B;

FIG. 16 is a plan view of a part of a display panel according to a fourth exemplary embodiment of the present disclosure;

FIG. 17 is a cross-sectional view taken along a line IV-IV′ of FIG. 16 according to an exemplary embodiment of the present disclosure;

FIG. 18 is a plan view of a part of a display panel according to a fifth exemplary embodiment of the present disclosure;

FIG. 19 is a cross-sectional view taken along a line V-V′ of FIG. 18 according to an exemplary embodiment of the present disclosure; and

FIG. 20 is a plan view of a part of a display panel according to a sixth exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiment of the present disclosure will be described in detail with reference to the drawings.

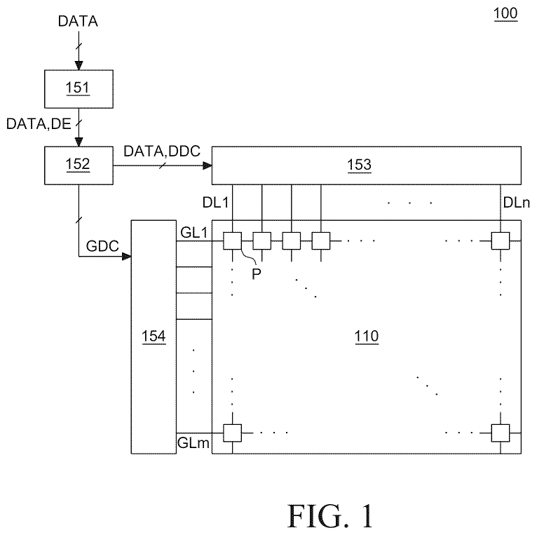

FIG. 1 is a block diagram of a display device according to an exemplary embodiment of the present disclosure.

Referring to FIG. 1, a display device 100 according to an exemplary embodiment of the present disclosure may include an image processor 151, a timing controller 152, a data driver 153, a gate driver 154, and a display panel 110.

The image processor 151 may output a data signal DATA and a data enable signal DE through a data signal DATA supplied from the outside.

The image processor 151 may output one or more of a vertical synchronization signal, a horizontal synchronization signal, and a clock signal in addition to the data enable signal DE.

The timing controller 152 receives the data enable signal DE or the data signal DATA, together with driving signals including the vertical synchronization signal, the horizontal synchronization signal, the clock signal, etc., from the image processor 151. The timing controller 152 may output a gate timing control signal GDC for controlling operation timing of the gate driver 154 and a data timing control signal DDC for controlling operation timing of the data driver 153 based on the driving signals.

The data driver 153 may sample and latch the data signal DATA supplied from the timing controller 152 in response to the data timing control signal DDC supplied from the timing controller 152. Then, the data driver 153 may convert the data signal DATA into a gamma reference voltage to output it. For example, the data driver 153 may output the data signal DATA through data lines DLI to DLn.

The gate driver 154 may output a gate signal while shifting a level of a gate voltage in response to the gate timing control signal GDC supplied from the timing controller 152. The gate driver 154 may output the gate signal through gate lines GL1 to GLm.

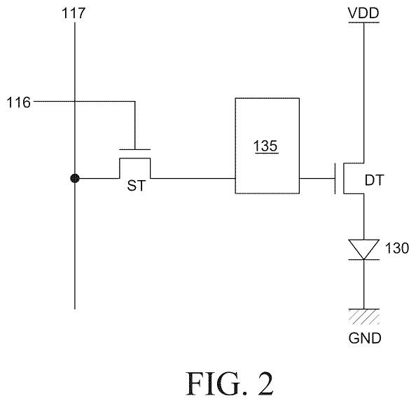

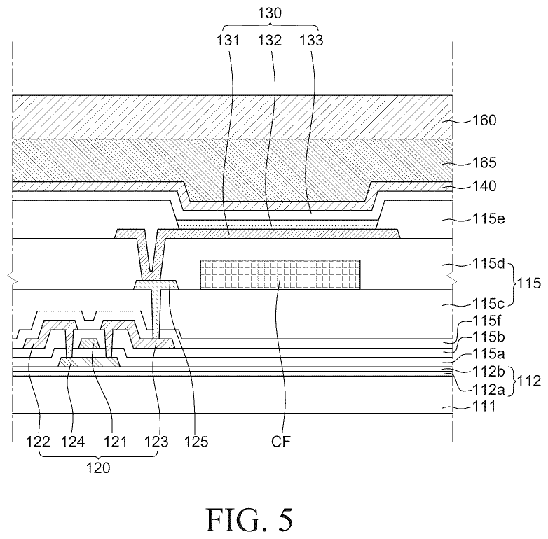

The display panel 110 may display an image while a sub-pixel P emits light in response to the data signal DATA and the gate signal supplied from the data driver 153 and the gate driver 154. A detailed structure of the sub-pixel P will be described with reference to FIG. 2 and FIG. 5.

FIG. 2 is a circuit diagram of a sub-pixel of the display device according to exemplary embodiments of the present disclosure.

Referring to FIG. 2, the sub-pixel of the display device according to exemplary embodiments of the present disclosure may include a switching transistor ST, a driving transistor DT, a compensation circuit 135, and a light emitting element 130.

The light emitting element 130 may operate to emit light according to a driving current formed by the driving transistor DT.

The switching transistor ST may perform a switching operation such that a data signal supplied through a data line 117 is stored as a data voltage in a capacitor in response to a gate signal supplied through a gate line 116.

Further, the driving transistor DT may operate such that a constant driving current flows between a high-potential power line VDD and a low-potential power line GND in response to the data voltage stored in the capacitor.

The compensation circuit 135 is configured to compensate for a threshold voltage or the like of the driving transistor DT. The compensation circuit 135 may include one or more transistors and capacitors. A configuration of the compensation circuit 135 may vary depending on a compensation method.

FIG. 2 illustrates, for example, the sub-pixel having a 2T (Transistor) 1C (Capacitor) structure including the switching transistor ST, the driving transistor DT, the capacitor, and the light emitting element 130. However, if the compensation circuit 135 is added, the sub-pixel may have various structures, such as 3T1C, 4T2C, 5T2C, 6T1C, 6T2C, 7T1C, 7T2C, etc.

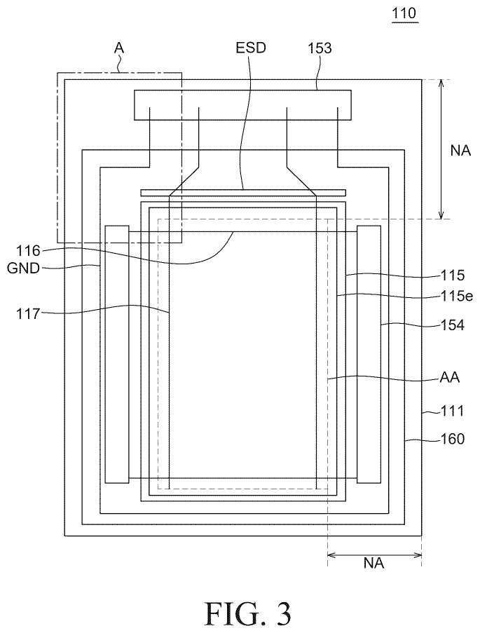

FIG. 3 is a plan view of a display panel according to a first exemplary embodiment of the present disclosure.

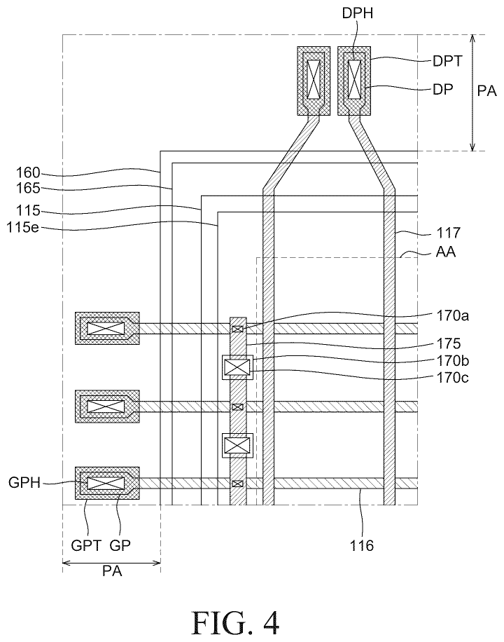

FIG. 4 is an enlarged view of an area A of FIG. 3 according to an exemplary embodiment of the present disclosure.

FIG. 5 is a cross-sectional view of one sub-pixel according to an exemplary embodiment of the present disclosure.

Referring to FIG. 3, the display device according to the first exemplary embodiment of the present disclosure may include the display panel 110, a flexible film, and a printed circuit board.

For example, the display panel 110 may include a substrate 111 and an encapsulation substrate 160.

The display panel 110 is configured to display images to a user.

The display panel 110 may include a display element configured to display images, a driving element configured to operate the display element, and lines configured to transmit various signals to the display element and the driving element. The display element may be defined in different manners depending on the type of the display panel 110. For example, when the display panel 110 is an organic light emitting display panel, the display element may be an organic light emitting element including an anode, an organic emission layer, and a cathode.

Hereinafter, the display panel 110 is assumed as an organic light emitting display panel. However, the display panel 110 is not limited to the organic light emitting display panel.

The display panel 110 may include a display area AA and a non-display area NA.

The display area AA is an area of the display panel 110 in which images are displayed.

The display area AA may include a plurality of sub-pixels constituting a plurality of pixels, and a circuit for driving the plurality of sub-pixels. The plurality of sub-pixels may be minimum units constituting the display area AA. The display element may be disposed in each of the plurality of sub-pixels. The plurality of sub-pixels may constitute a pixel. For example, each of the plurality of sub-pixels may include an organic light emitting element including an anode, an organic emission layer, and a cathode. However, the present disclosure is not limited thereto. Further, the circuit for driving the plurality of sub-pixels may include driving elements, lines, etc. For example, the circuit may include a thin film transistor, a storage capacitor, a gate line, a data line, etc., but is not limited thereto.

The non-display area NA is an area in which no image is displayed.

FIG. 3 illustrates that the non-display area NA encloses the display area AA having a quadrangular shape. However, the shape and disposition of the display area AA and the non-display area NA are not limited to the example illustrated in FIG. 3.

That is, the display area AA and the non-display area NA may be suitable for the design of an electronic device equipped with the display device. For example, the display area AA may have other shapes, such as a pentagonal shape, a hexagonal shape, a circular shape, an elliptical shape, or the like.

Also, the display device may include various additional components configured to generate various signals or drive the pixels in the display area AA. The additional components for driving the pixel may include an inverter circuit, a multiplexer, an electrostatic discharge (ESD) circuit, etc. The display device may also include additional components related to functions other than the function of driving the pixel. For example, the display device may include additional components for providing a touch sensing function, a user authentication function (e.g., fingerprint recognition), a multi-level pressure sensing function, a tactile feedback function, etc. The additional components may be located in the non-display area NA and/or an external circuit connected to a connection interface.

For example, the gate driver 154, a static electricity discharge element ESD, and the data driver 153 required to perform a display function may be disposed in the non-display area NA. The gate driver 154 and the static electricity discharge element ESD may be simultaneously formed with the thin film transistor disposed in the display area AA. The data driver 153 may be attached to one lateral side of the display panel 110, but is not limited thereto.

To implement a narrow bezel structure, the gate driver 154 may be formed directly on the substrate 111, particularly, on left and right sides of the non-display area NA. While the gate driver 154 is formed directly on the substrate 111, static electricity may be introduced through the gate line 116.

The data driver 153 having a more complicated structure than the gate driver 154 may be separately fabricated and then may be mounted on the substrate 111 or connected to the substrate 111 through a connection element, such as an FPCB. FIG. 3 illustrates that the data driver 153 is mounted on the substrate 111. In this case, static electricity may be introduced through the data line 117.

Further, the flexible film serves to supply signals to the plurality of sub-pixels and the circuit disposed in the display area AA. The flexible film may be electrically connected to the display panel 110. The flexible film may be disposed at one end of the non-display area NA of the display panel 110 to supply a power voltage, a data voltage, etc. to the plurality of sub-pixels and the circuit disposed in the display area AA. A drive IC, such as a data driver IC, may be disposed on the flexible film.

The printed circuit board may be disposed at one end of the flexible film and connected to the flexible film. The printed circuit board is configured to supply signals to the drive IC. The printed circuit board may supply the drive IC with various signals, such as driving signals, data signals, etc.

As described above, static electricity may be introduced through the gate line 116 or the data line 117 during the process.

Therefore, in the first exemplary embodiment of the present disclosure, the static electricity discharge element ESD may be further provided to suppress the introduction of static electricity into the display area AA from the outside through the data line 117 or a driving current line. The static electricity discharge element ESD may be disposed at ends of the data line 117 and the driving current line. For example, the static electricity discharge element ESD may be disposed on an upper side of the display area AA on which the data driver 153 is disposed. Also, the static electricity discharge element ESD may be disposed adjacent to the display area AA. The static electricity discharge element ESD may be configured as a thin film transistor. Therefore, when the thin film transistor is formed in the display area AA, the static electricity discharge element ESD may also be simultaneously formed.

A ground line GND may be disposed to enclose the display area AA and the gate driver 154 and ESD disposed therearound. The ground line GND may be disposed to be branched at the data driver 153. A dam may be disposed outside the ground line GND.

Meanwhile, if the gate line 116 is separated from each other as in the prior art, it may be vulnerable to static electricity. This is the same as for the data line 117. Also, white OLED (WOLED) TVs and monitors (MNT) are required to have a reduced reflectivity, a high resolution, a high aperture ratio, and a high PPI, but may be vulnerable to static electricity and reflectivity due to an increase in pattern density.

Thus, in the first exemplary embodiment of the present disclosure, a connection line may be provided between the gate lines 116 (or the data lines 117) so as to disperse static electricity.

Details of the connection line will be described with further reference to FIG. 4 and FIG. 5.

Referring to FIG. 3 through FIG. 5, the substrate 111 may be divided into the display area AA and the non-display area NA outside the display area AA.

A thin film transistor 120 and a light emitting element 130 may be disposed in the display area AA of the substrate 111.

The non-display area NA of the substrate 111 may include a pad area PA.

A gate pad GP and a data pad DP may be disposed in the pad area PA.

The substrate 111 serves to support and protect components of the display device disposed thereon.

Recently, the flexible substrate 111 may be used by using a flexible material, such as plastic, having flexibility.

The flexible substrate 111 may be in the form of a film including one of the group consisting of a polyester-based polymer, a silicone-based polymer, an acrylic polymer, a polyolefin-based polymer, and a copolymer thereof.

A light shielding layer (not shown) may be disposed on the substrate 111.

The light shielding layer may be made of a metallic material having a light shielding function in order to block introduction of external light into a semiconductor layer 124.

For example, the light shielding layer may be configured by a single layer or a multi-layer made of any one of opaque metals, such as aluminum (Al), chromium (Cr), tungsten (W), titanium (Ti), neodymium (Nd), nickel (Ni), molybdenum (Mo) and copper (Cu), or an alloy thereof.

A buffer layer 112 may be disposed on the substrate 111 on which the light shielding layer is disposed.

The buffer layer 112 is a functional layer for protecting various electrodes and lines from impurities, such as moisture, oxygen, alkali ions, etc., introduced from the substrate 111 or a lower portion thereof. The buffer layer 112 may have a multilayer structure composed of a first buffer layer 112a and a second buffer layer 112b. However, the present disclosure is not limited thereto.

For example, the buffer layer 112 may be made of silicon oxide (SiOx), silicon nitride (SiNx), or a multilayer structure thereof, but is not limited thereto. The buffer layer 112 may be omitted depending on the type of the thin film transistor 120.

The buffer layer 112 may include a contact hole exposing a part of the light shielding layer.

The thin film transistor 120 may be disposed on the buffer layer 112.

The thin film transistor 120 in the display area AA may be a driving transistor. For convenience, only the driving transistor 120 is illustrated in FIG. 5. Other switching transistors, sensing transistors, compensation circuits, etc. may be included in the display device.

In this case, the driving transistor 120 may transmit a current, which has been transmitted through a power line, to an anode 131 in response to a signal received from a switching transistor. Then, the driving transistor 120 may control light emission by the current transmitted to the anode 131.

To this end, the driving transistor 120 may include a gate electrode 121, the semiconductor layer 124, a source electrode 122, and a drain electrode 123.

The switching transistor may be turned on by a gate pulse supplied through the gate line 116 and may transmit a data voltage supplied through the data line 117 to the gate electrode 121 of the driving transistor 120.

The semiconductor layer 124 may be disposed on the second buffer layer 112b.

The semiconductor layer 124 may be made of polysilicon (p-Si). In this case, a predetermined region thereof may be doped with an impurity. Also, the semiconductor layer 124 may be made of amorphous silicon (a-Si) or various organic semiconductor materials, such as pentacene or the like. Further, the semiconductor layer 124 may be made of an oxide semiconductor.

The oxide semiconductor has excellent mobility and uniformity. The oxide semiconductor may be made of a quaternary metal oxide, such as an indium tin gallium zinc oxide (InSnGaZnO)-based material, a ternary metal oxide, such as an indium gallium zinc oxide (InGaZnO)-based material, an indium tin zinc oxide (InSnZnO)-based material, an indium aluminum zinc oxide (InAlZnO)-based material, a tin gallium zinc oxide (SnGaZnO)-based material, an aluminum gallium zinc oxide (AlGaZnO)-based material, and a tin aluminum zinc oxide (SnAlZnO)-based material, a binary metal oxide, such as an indium zinc oxide (InZnO)-based material, a tin zinc oxide (SnZnO)-based material, an aluminum zinc oxide (AlZnO)-based material, a zinc magnesium oxide (ZnMgO)-based material, a tin magnesium oxide (SnMgO)-based material, an indium oxide (InO)-based material, a tin oxide (SnO)-based material, an indium gallium oxide (InGaO)-based material, a zinc oxide (ZnO)-based material, an indium magnesium oxide (InMgO)-based material, or the like. Composition ratios of the respective elements are not limited.

The semiconductor layer 124 may include a source region and a drain region containing p-type or n-type impurities, and a channel region between the source region and the drain region. The semiconductor layer 124 may further include a low concentration-doped region between the channel region and the source and drain regions adjacent to the channel region. However, the present disclosure is not limited thereto.

The source region and the drain region are doped with a high concentration of impurities, and may be connected to the source electrode 122 and the drain electrode 123, respectively, of the thin film transistor 120.

P-type impurities or n-type impurities may be used for the impurity ions. The p-type impurities may be one of boron (B), aluminum (Al), gallium (Ga), and indium (In). The n-type impurities may be one of phosphorus (P), arsenic (As), and antimony (Sb).

The channel region may be doped with the n-type impurities or p-type impurities depending on the structure of an NMOS or PMOS thin film transistor.

A gate insulating layer 115a may be disposed on the semiconductor layer 124. For example, the gate insulating layer 115a may be made of an inorganic insulating material, such as silicon oxide (SiOx) or silicon nitride (SiNx), or may be made of an organic insulating material.

The gate electrode 121 and the gate line 116 may be disposed on the gate insulating layer 115a.

Also, the gate pad GP may be disposed on the gate insulating layer 115a in the non-display area NA. For example, the gate pad GP may be provided at one end of each gate line 116 extending to the pad area PA.

The gate electrode 121, the gate line 116, and the gate pad GP may be made of various conductive materials, such as magnesium (Mg), aluminum (Al), nickel (Ni), chromium (Cr), molybdenum (Mo), tungsten (W), gold (Au), or an alloy thereof.

Further, an interlayer insulating layer 115b may be disposed on the gate electrode 121, the gate line 116, and the gate pad GP.

For example, the interlayer insulating layer 115b may be made of silicon oxide (SiOx), silicon nitride (SiNx), or a multilayer structure thereof.

In the first exemplary embodiment of the present disclosure, a first contact hole 170a exposing a part of the gate line 116 may be formed by selectively removing a portion of the interlayer insulating layer 115b. The first contact hole 170a may be located in the non-display area NA adjacent to the display area AA, but is not limited thereto. For example, the first contact hole 170a may be disposed in the non-display area NA between the display area AA and the gate pad GP.

Although not illustrated in the drawings in detail, at least one insulating layer of the buffer layer 112, the gate insulating layer 115a, and the interlayer insulating layer 115b may extend to the non-display area NA including the pad area PA.

The source electrode 122, the drain electrode 123, and the data line 117 may be disposed on the interlayer insulating layer 115b.

The data pad DP may be disposed on the interlayer insulating layer 115b in the non-display area NA. For example, the data pad DP may be provided at one end of each data line 117 extending to the pad area PA.

Also, a connection line 175 connecting the gate lines 116 through the first contact hole 170a may be disposed in the non-display area NA. For example, the connection line 175 may be disposed in the non-display area NA between the display area AA and the gate pad GP.

The source electrode 122, the drain electrode 123, the data line 117, the data pad DP, and the connection line 175 may be configured by a single layer or a multi-layer made of various conductive materials, e.g., a metallic material, such as aluminum (Al), molybdenum (Mo), chromium (Cr), gold (Au), titanium (Ti), nickel (Ni), neodymium (Nd), and copper (Cu), or an alloy thereof. However, the present disclosure is not limited thereto.

A protection layer 115f may be disposed on the thin film transistor 120 configured as described above.

Also, a planarization layer 115 may be disposed on the protection layer 115f.

The planarization layer 115 may be an overcoating layer.

The planarization layer 115 may have a multilayer structure composed of at least two layers. For example, the planarization layer 115 may include a first planarization layer 115c and a second planarization layer 115d. In this case, for example, the first planarization layer 115c may be disposed to cover the thin film transistor 120 and expose a part of the drain electrode 123 of the thin film transistor 120. However, the present disclosure is not limited thereto. The planarization layer 115 may be configured by a single layer.

The planarization layer 115 may extend to the non-display area NA excluding the pad area PA.

The planarization layer 115 may have a thickness of about 2 μm, but is not limited thereto.

The thin film transistor 120 may be classified into an inverted staggered structure and a coplanar structure depending on the positions of the components of the thin film transistor 120. For example, in a thin film transistor having the inverted staggered structure, a gate electrode may be located on the opposite side to a source electrode and a drain electrode with respect to the semiconductor layer. As shown in FIG. 5, in the thin film transistor 120 having the coplanar structure, the gate electrode 121 may be located on the same side as the source electrode 122 and the drain electrode 123 with respect to the semiconductor layer 124.

Although the thin film transistor 120 having the coplanar structure is illustrated in FIG. 5, the present disclosure is not limited thereto. The display device according to exemplary embodiments of the present disclosure may include a thin film transistor having the inverted staggered structure. Also, some thin film transistors 120 may have the coplanar structure, and other some thin film transistors 120 may have the inverted staggered structure.

A connection electrode 125 for electrically connecting the thin film transistor 120 and the light emitting element 130 may be disposed on the first planarization layer 115c. Also, although not shown in FIG. 5, various metallic layers serving as lines/electrodes, such as signal lines, may be disposed on the first planarization layer 115c.

Also, a color filter CF may be disposed on the first planarization layer 115c, but the present disclosure is not limited thereto. The color filter CF may be omitted depending on the type of the light emitting element 130.

The color filter CF in each sub-pixel may have one of red, green, and blue colors. The color filter CF may not be disposed in a sub-pixel that implements white. The arrangement of red, green, and blue may vary, and a black matrix which can absorb external light may be provided between the color filters CF.

In a bottom emission method, the color filter CF may be located under the electrode 131.

Further, the second planarization layer 115d may be disposed on the first planarization layer 115c and the connection electrode 125. In the display device according to the first exemplary embodiment of the present disclosure, the planarization layer 115 is composed of two layers due to an increase in number of various signal lines as the display panel 110 has a higher resolution. Therefore, it becomes more difficult to secure a minimum gap when placing all of lines on one layer. Accordingly, an additional layer is provided. The additional layer (the second planarization layer 115d) may provide a sufficient margin for line arrangement, which makes it easier to design the layout of lines/electrodes. If a dielectric material is used for the planarization layer 115 configured by a multi-layer, the planarization layer 115 may serve to generate a capacitance between the metallic layers. However, as described above, the planarization layer 115 may be configured by a single layer.

The second planarization layer 115d may be provided to expose a part of the connection electrode 125. The drain electrode 123 of the thin film transistor 120 may be electrically connected to the anode 131 of the light emitting element 130 by the connection electrode 125.

The light emitting element 130 composed of the anode 131, an organic layer 132, and a cathode 133 may be disposed on the second planarization layer 115d.

Herein, in the first exemplary embodiment of the present disclosure, a second contact hole 170b exposing a part of the protection layer 115f may be formed by selectively removing a portion of the planarization layer 115. The second contact hole 170b may be located on the connection line 175 between neighboring gate lines 116.

Also, in the first exemplary embodiment of the present disclosure, a third contact hole 170c exposing a part of the connection line 175 may be formed by selectively removing a portion of the protection layer 115f. For example, the third contact hole 170c may expose an upper surface of the connection line 175 between neighboring gate lines 116.

The anode 131 may be disposed on the second planarization layer 115d.

The anode 131 is an electrode serving to supply holes to the organic layer 132, and may be connected to the thin film transistor 120 through a contact hole formed in a planarization layer 115.

Meanwhile, the display device may be implemented in a top emission method or a bottom emission method. In the top emission method, a reflective layer made of an opaque conductive material with a high reflectivity, e.g., silver (Ag), aluminum (Al), gold (Au), molybdenum (Mo), tungsten (W), chromium (Cr), or an alloy thereof, may be added under the anode 131. Thus, light emitted from the organic layer 132 is reflected by the anode 131 and directed upwards, i.e., in a direction toward the cathode 133. In the bottom emission method, the anode 131 may be made of a transparent conductive material, such as indium tin oxide (ITO), indium zinc oxide (IZO), indium gallium zinc oxide (IGZO), or the like. Hereinafter, the display panel 110 of the present disclosure will be described as a bottom emission display panel.

A gate pad terminal GPT and a data pad terminal DPT may be disposed on the second planarization layer 115d in the non-display area NA. For example, the gate pad terminal GPT may be electrically connected to the gate pad GP through a gate pad contact hole GPH. Also, the data pad terminal DPT may be connected to the data pad DP through a data pad contact hole DPH.

Meanwhile, in the first exemplary embodiment of the present disclosure, the upper surface of the connection line 175 exposed by the third contact hole 170c may be removed through an additional etching process after the anode 131 is formed (patterned). Therefore, the connection line 175 between neighboring gate lines 116 may be disconnected.

A bank 115e may be disposed on the anode 131 and the second planarization layer 115d.

The bank 115e disposed on the anode 131 and the second planarization layer 115d may partition an area where light is actually emitted, i.e., an emission area, to define sub-pixels.

For example, the bank 115e may be formed by photolithography after a photoresist is formed on the anode 131.

In order to form the organic layer 132 of the light emitting element 130, a fine metal mask (FMM) may be used as a deposition mask.

In order to suppress damage which may be caused by a contact with the deposition mask disposed on the bank 115e and maintain a predetermined distance between the bank 115e and the deposition mask, a spacer may be disposed on the bank 115e. The spacer may be made of one of polyimide, photo acryl, and benzocyclobutene (BCB) which are transparent organic materials.

Herein, the bank 115e of the emission area may be removed to expose a part of the anode 131.

The bank 115e may extend to a part of the non-display area NA excluding the pad area PA, but is not limited thereto.

Further, for example, the bank 115e may have a thickness of about 1 μm, but is not limited thereto.

The organic layer 132 may be disposed between the anode 131 and the cathode 133.

The organic layer 132 serves to emit light and includes at least one of a hole injection layer (HIL), a hole transport layer (HTL), an emission layer, an electron transport layer (ETL), and an electron injection layer (EIL). Some components may be omitted depending on the structure or characteristics of the display device. Herein, as the emission layer, an electroluminescent emission layer and an inorganic emission layer can be applied.

The hole injection layer is disposed on the anode 131 to facilitate the injection of holes.

The hole transport layer is disposed on the hole injection layer to facilitate the transmission of holes to the emission layer.

The emission layer is disposed on the hole transport layer and contains a material which emits light of a specific color to emit light of the specific color. The light emitting material may be a phosphorescent material or a fluorescent material.

The electron injection layer may be further disposed on the electron transport layer. The electron injection layer is an organic layer which facilitates the injection of electrons from the cathode 133 and may be omitted depending on the structure and characteristics of the display device.

Further, an electron blocking layer and/or a hole blocking layer which blocks the flow of holes or electrons may be further disposed adjacent to the emission layer. In this case, it is possible to suppress the phenomenon that electrons move from the emission layer to pass through the adjacent hole transparent layer when the electrons are injected into the emission layer. Also, it is possible to suppress the phenomenon that holes move from the emission layer to pass through the adjacent electron transparent layer when the holes are injected into the emission layer. Therefore, it is possible to improve the luminous efficiency.

The cathode 133 may be disposed on the organic layer 132.

The cathode 133 serves to supply electrons to the organic layer 132. Since the cathode 133 needs to supply electrons, the cathode 133 may be made of a metallic material which is a conductive material having a low work function, such as magnesium or silver-magnesium, but is not limited thereto.

Although not illustrated in the drawings, a capping layer may be also disposed on the cathode 133.

The capping layer may serve to protect the light emitting element 130 and help light generated from the organic layer 132 to be emitted efficiently toward the outside.

An inorganic layer 140 may be disposed on the cathode 133. However, the present disclosure is not limited thereto. The inorganic layer 140 may not be disposed.

For example, the inorganic layer 140 may be made of an inorganic insulating material.

The inorganic layer 140 may delay the moisture permeation in an upper portion, and suppress a defect caused by dent or foreign matter.

Herein, to delay moisture permeation, the inorganic layer 140 may be made of silicon oxide (SiOx), silicon nitride (SiNx), or a multi-layer thereof, but is not limited thereto.

The encapsulation substrate 160 may be disposed on the inorganic layer 140 via an adhesive layer 165. However, the present disclosure is not limited thereto. An encapsulation structure of a plurality of layers including a sealing member and a reinforcement substrate may be disposed on the inorganic layer 140.

For example, the adhesive layer 165 may serve to delay lateral moisture permeation.

For example, the adhesive layer 165 may further contain a moisture absorbent, such as a getter, in addition to isobutyl rubber resin. The moisture absorbent may include calcium oxide.

The moisture absorbent may be particles having moisture absorption properties, and can absorb moisture and oxygen from the outside. Thus, the moisture absorbent can minimize the permeation of moisture and oxygen into the display area AA.

For example, the adhesive layer 165 may have a thickness of 40 μm to 60 μm.

The adhesive layer 165 may extend to the non-display area NA excluding the pad area PA. For example, the adhesive layer 165 may be disposed to cover the connection line 175.

The encapsulation substrate 160 may be disposed on the adhesive layer 165.

The encapsulation substrate 160 may protect the light emitting element 130 together with the adhesive layer 165. The encapsulation substrate 160 may protect the light emitting element 130 from external moisture, oxygen, impacts, etc.

For example, the encapsulation substrate 160 may serve to suppress moisture permeation through the front surface.

For example, the encapsulation substrate 160 may be made of steel use stainless (SUS) or Invar, but is not limited thereto. Herein, Invar is one of alloys of nickel and iron, and has a very low thermal expansion coefficient and thus is relatively stable to temperature changes.

For example, the encapsulation substrate 160 may have a thickness of 70 μm to 80 μm.

The encapsulation substrate 160 may extend to the non-display area NA excluding the pad area PA. For example, the encapsulation substrate 160 may be disposed to cover the connection line 175.

In the first exemplary embodiment of the present disclosure, the connection line 175 is provided between the gate lines 116 to disperse static electricity. Thus, it is possible to suppress damage to the display panel 110 during a process. Therefore, it is possible to improve the reliability of the display device.

Meanwhile, the connection line of the present disclosure may be disposed on the same layer as the semiconductor layer under the gate lines. In this case, static electricity can be dispersed from the formation of the gate lines to the formation of the anode. Details thereof will be described with reference to the accompanying drawings.

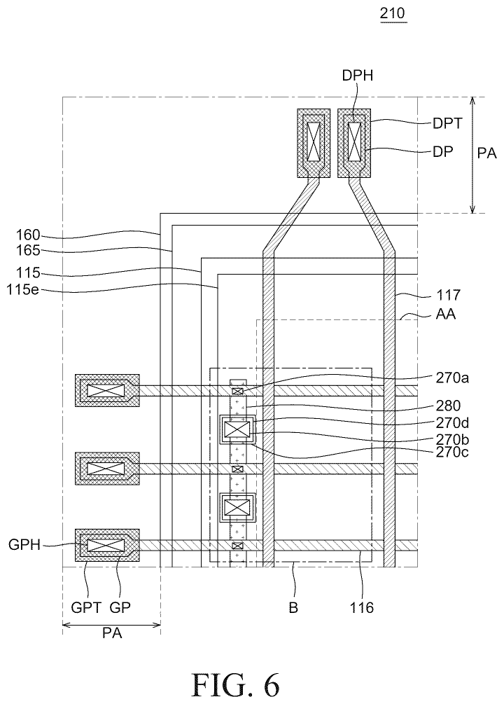

FIG. 6 is a plan view of a part of a display panel according to a second exemplary embodiment of the present disclosure.

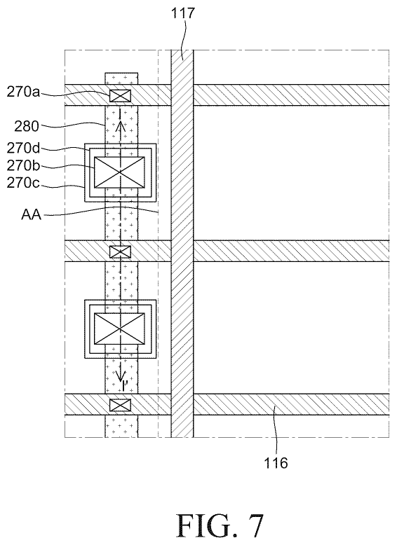

FIG. 7 is an enlarged view of an area B of FIG. 6 according to an exemplary embodiment of the present disclosure.

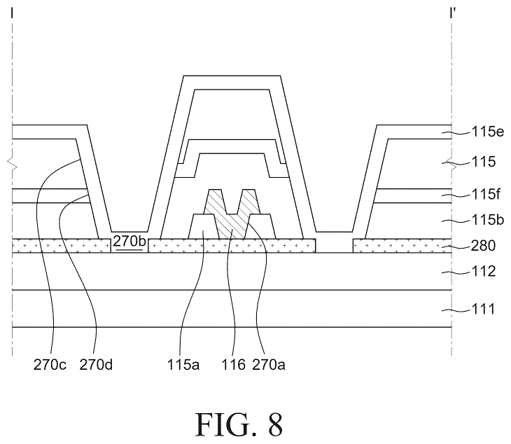

FIG. 8 is a cross-sectional view taken along a line I-I′ of FIG. 7 according to an exemplary embodiment of the present disclosure.

A display panel 210 according to the second exemplary embodiment of FIG. 6 through FIG. 8 is substantially the same as the first exemplary embodiment of FIG. 3 and FIG. 4 except that a connection line 280 is disposed on the same layer as the semiconductor layer under the gate line 116. Therefore, redundant description thereof will be omitted. The same components will be denoted by the same reference numerals. Hereinafter, description of the same reference numerals may refer to FIG. 1 through FIG. 5.

Referring to FIG. 6 through FIG. 8, the substrate 111 may be divided into the display area AA and the non-display area NA outside the display area AA.

The thin film transistor 120 and the light emitting element 130 may be disposed in the display area AA of the substrate 111.

The non-display area NA of the substrate 111 may include the pad area PA.

The gate pad GP and the data pad DP may be disposed in the pad area PA.

A light shielding layer (not shown) may be disposed on the substrate 111.

The buffer layer 112 may be disposed on the substrate 111 on which the light shielding layer is disposed.

For example, the buffer layer 112 may have a multilayer structure composed of the first buffer layer 112a and the second buffer layer 112b, but is not limited thereto.

The thin film transistor 120 may be disposed on the buffer layer 112.

The semiconductor layer 124 may be disposed on the second buffer layer 112b.

The semiconductor layer 124 may be made of an oxide semiconductor.

For example, the semiconductor layer 124 may be made of a transparent metal oxide, such as indium tin oxide (ITO), indium zinc oxide (IZO), indium gallium zinc oxide (IGZO), or the like, but is not limited thereto.

Also, the connection line 280 may be disposed in the non-display area NA. For example, the connection line 280 may be disposed in a direction crossing the gate line 116. Further, for example, the connection line 280 may be disposed in the non-display area NA between the display area AA and the gate pad GP in a direction crossing the gate line 116. For example, the connection line 280 may be disposed along the data line 117 in a longitudinal direction (in parallel) from the first gate line 116 to the last gate line 116.

For example, the connection line 280 may be disposed on the same layer as the semiconductor layer 124. Also, the connection line 280 may be made of a transparent metal oxide, such as indium tin oxide (ITO), indium zinc oxide (IZO), indium gallium zinc oxide (IGZO), or the like, but is not limited thereto.

The gate insulating layer 115a may be disposed on the semiconductor layer 124 and the connection line 280.

In the second exemplary embodiment of the present disclosure, a first contact hole 270a exposing a part of the connection line 280 may be formed by selectively removing a portion of the gate insulating layer 115a. The first contact hole 270a may be located in the non-display area NA adjacent to the display area AA, but is not limited thereto. For example, the first contact hole 270a may be disposed in the non-display area NA between the display area AA and the gate pad GP.

The gate electrode 121 and the gate line 116 may be disposed on the gate insulating layer 115a. For example, the gate line 116 may extend to the pad area PA of the non-display area NA in a second direction crossing the connection line 280.

Also, the gate pad GP may be disposed on the gate insulating layer 115a in the non-display area NA. For example, the gate pad GP may be provided at one end of each gate line 116 extending to the pad area PA.

In the second exemplary embodiment of the present disclosure, the gate line 116 may be electrically connected to the connection line 280 through the first contact hole 270a. Therefore, all of the gate lines 116 may be connected to each other by the connection line 280. Also, even when static electricity is generated in a subsequent process, static electricity can be dispersed through the connected gate lines 116.

Further, the interlayer insulating layer 115b may be disposed on the gate electrode 121, the gate line 116, and the gate pad GP.

In the second exemplary embodiment of the present disclosure, a second contact hole 270b exposing a part of the connection line 280 may be formed by selectively removing a portion of the interlayer insulating layer 115b. The second contact hole 270b may be located in the non-display area NA adjacent to the display area AA, but is not limited thereto. For example, the second contact hole 270b may be located in the non-display area NA between the display area AA and the gate pad GP. For example, the second contact hole 270b may be located on the connection line 280 between the gate lines 116. For example, the second contact hole 270b may have a sufficient lateral width to expose a part of the connection line 280. Thus, the connection line 280 can be reliably disconnected through a process of disconnecting the connection line 280 to be described below.

The source electrode 122, the drain electrode 123, and the data line 117 may be disposed on the interlayer insulating layer 115b.

The data pad DP may be disposed on the interlayer insulating layer 115b in the non-display area NA. For example, the data pad DP may be provided at one end of each data line 117 extending to the pad area PA.

The protection layer 115f may be disposed on the thin film transistor 120 configured as described above.

Also, the planarization layer 115 may be disposed on the protection layer 115f.

The planarization layer 115 may be an overcoating layer.

The planarization layer 115 may extend to the non-display area NA excluding the pad area PA.

The light emitting element 130 composed of the anode 131, the organic layer 132, and a cathode 133 may be disposed on the planarization layer 115.

Herein, in the second exemplary embodiment of the present disclosure, a third contact hole 270c exposing a part of the protection layer 115f may be formed by selectively removing a portion of the planarization layer 115. For example, the third contact hole 270c may be located on the second contact hole 270b. For example, the third contact hole 270c may be located on the connection line 280 between neighboring gate lines 116.

For example, the third contact hole 270c may have a greater lateral width than the second contact hole 270b.

In the second exemplary embodiment of the present disclosure, a fourth contact hole 270d exposing a part of the connection line 280 may be formed by selectively removing a portion of the protection layer 115f exposed by the third contact hole 270c. For example, the fourth contact hole 270d may be located on the second contact hole 270b. Thus, for example, the fourth contact hole 270d may expose an upper surface of the connection line 280 between neighboring gate lines 116.

For example, the fourth contact hole 270d may have a greater lateral width than the second contact hole 270b.

The anode 131 may be disposed on the second planarization layer 115d.

In the bottom emission method, the anode 131 may be made of a transparent conductive material, such as indium tin oxide (ITO), indium zinc oxide (IZO), indium gallium zinc oxide (IGZO), or the like. However, the present disclosure is not limited thereto. The top emission method can also be applied.

The gate pad terminal GPT and the data pad terminal DPT may be disposed on the second planarization layer 115d in the non-display area NA. For example, the gate pad terminal GPT may be electrically connected to the gate pad GP through the gate pad contact hole GPH, and the data pad terminal DPT may be connected to the data pad DP through the data pad contact hole DPH.

In the second exemplary embodiment of the present disclosure, a portion of the connection line 280 exposed by the second, third and fourth contact holes 270b, 270c and 270d may be removed through the same etching process when the anode 131 is formed (patterned). Therefore, the connection line 280 between neighboring gate lines 116 may be disconnected.

The bank 115e may be disposed on the anode 131 and the second planarization layer 115d.

The bank 115e may extend to a part of the non-display area NA excluding the pad area PA, but is not limited thereto.

The organic layer 132 may be disposed between the anode 131 and the cathode 133.

The cathode 133 may be disposed on the organic layer 132.

The inorganic layer 140 may be disposed on the cathode 133.

The encapsulation substrate 160 may be disposed on the inorganic layer 140 via the adhesive layer 165.

The adhesive layer 165 may extend to the non-display area NA excluding the pad area PA. For example, the adhesive layer 165 may be disposed to cover the connection line 280.

The encapsulation substrate 160 may be disposed on the adhesive layer 165.

The encapsulation substrate 160 may extend to the non-display area NA excluding the pad area PA. For example, the encapsulation substrate 160 may be disposed to cover the connection line 280.

In the second exemplary embodiment of the present disclosure, the connection line 280 may be disposed on the same layer as the semiconductor layer 124 under the gate line 116 to disperse static electricity. Thus, it is possible to more effectively disperse static electricity generated during a process from the formation of the gate line 116 to the formation of the anode 131. Therefore, it is possible to further improve the reliability of the display device.

Further, in the second exemplary embodiment of the present disclosure, the connection line 280 is made of a transparent metal oxide to minimize or at least reduce a reflectivity of the display panel. Therefore, low power consumption can be achieved. Particularly, the second exemplary embodiment of the present disclosure can contribute to the improvement in quality of WOLED TVs and monitors (MNT).

Furthermore, in the second exemplary embodiment of the present disclosure, the connection line 280 is made of the same transparent metal oxide as the anode 131. Thus, the connection line 280 can be patterned when the anode 131 is formed. Therefore, the process can be simplified.

Hereinafter, a process of manufacturing the display device according to the second exemplary embodiment of the present disclosure will be described in detail with reference to the accompanying drawings.

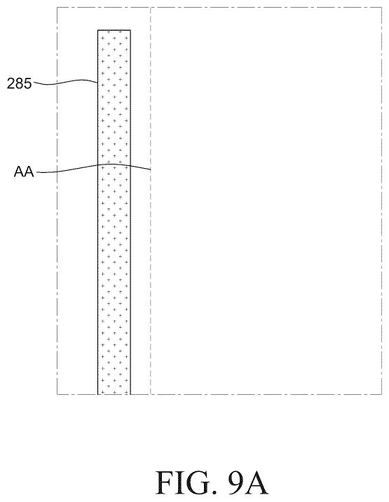

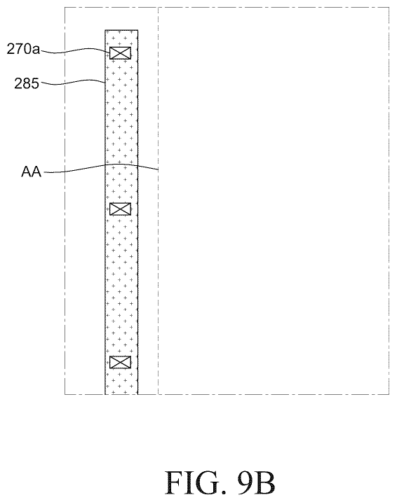

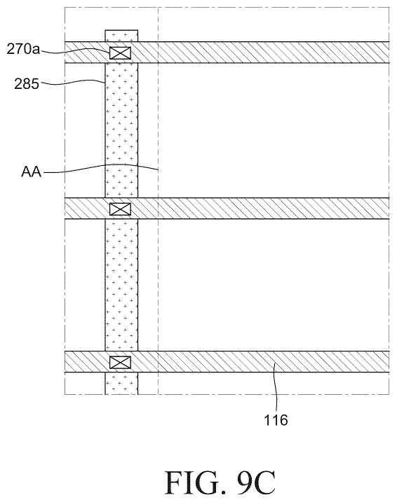

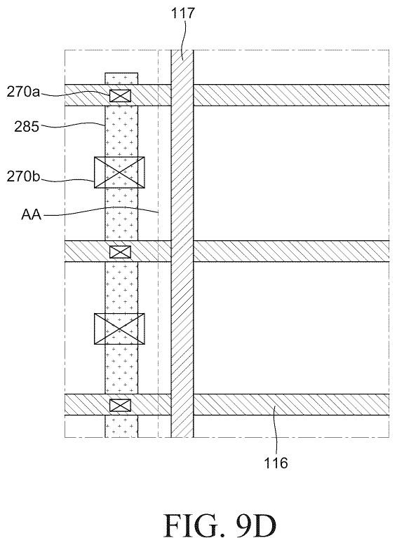

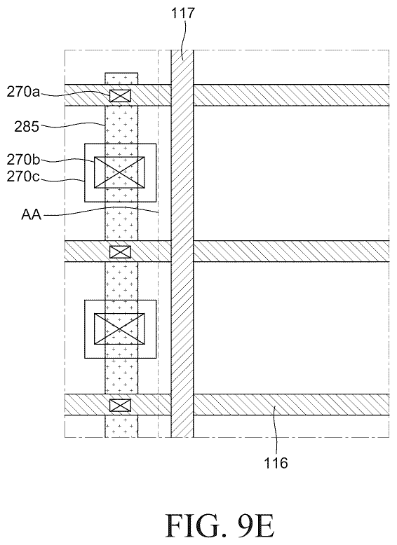

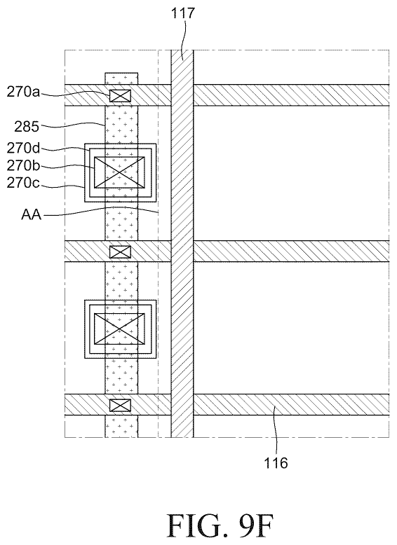

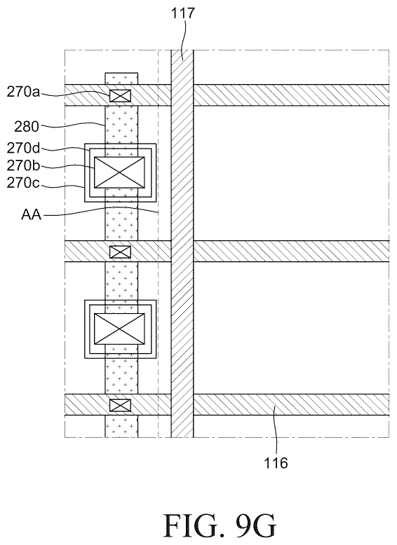

FIG. 9A through FIG. 9G are diagrams illustrating the process of manufacturing the display panel according to the second exemplary embodiment of the present disclosure of FIG. 7.

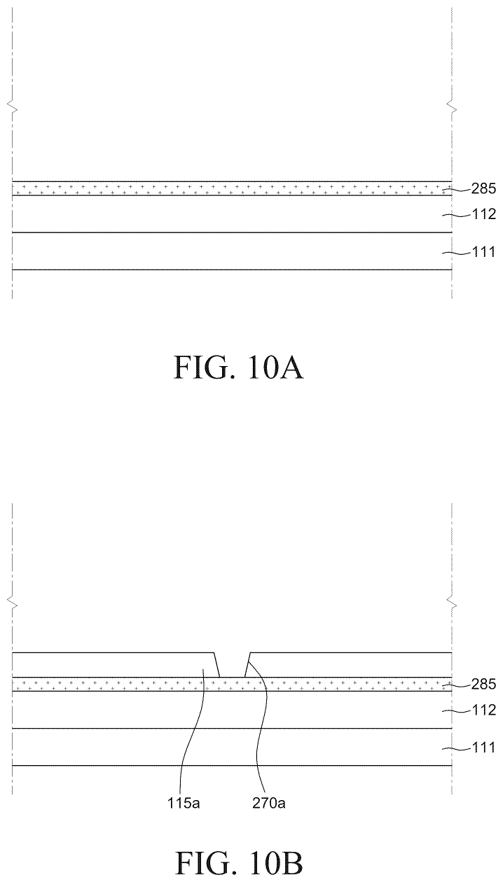

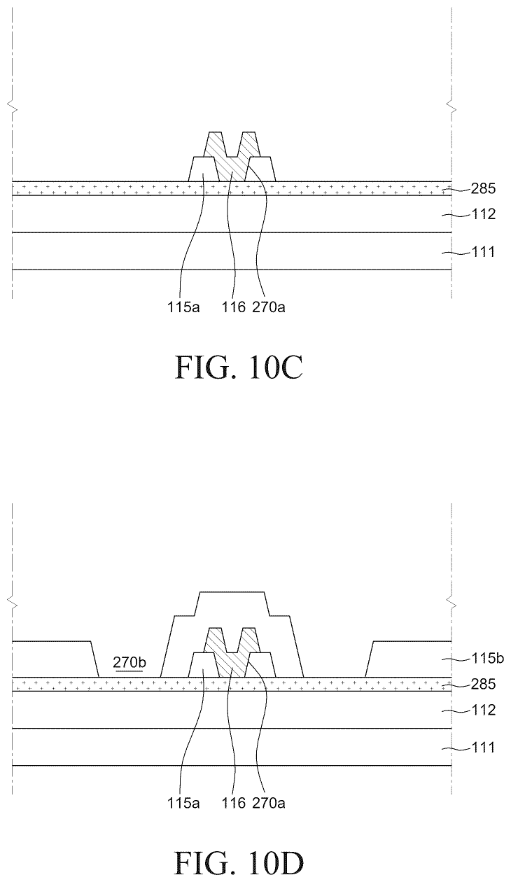

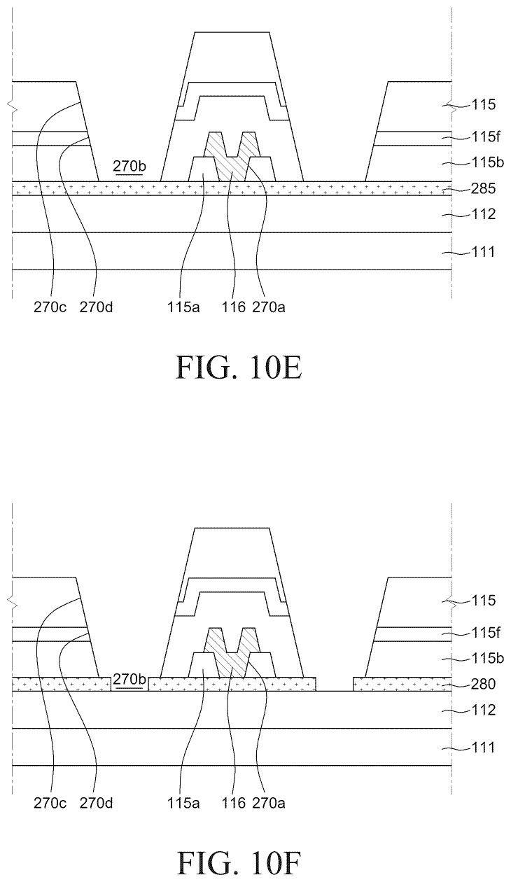

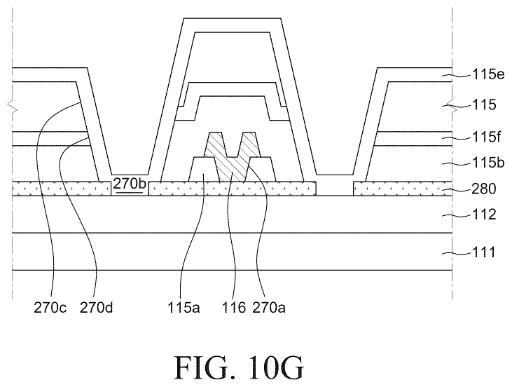

FIG. 10A through FIG. 10G are diagrams sequentially illustrating a process of manufacturing the display panel according to the second exemplary embodiment of the present disclosure of FIG. 8.

FIG. 9A through FIG. 9G and FIG. 10A through FIG. 10G illustrate an example of the process of manufacturing the display panel according to the second exemplary embodiment of the present disclosure. The same components will be denoted by the same reference numerals. Hereinafter, description of the same reference numerals may refer to FIG. 1 through FIG. 8.

First, referring to FIG. 9A and FIG. 10A, the buffer layer 112 may be disposed on the substrate 111 which is divided into the display area AA and the non-display area NA.

Then, the semiconductor layer 124 may be provided on the buffer layer 112.

The semiconductor layer 124 may be made of an oxide semiconductor.

For example, the semiconductor layer 124 may be made of a transparent metal oxide, such as indium tin oxide (ITO), indium zinc oxide (IZO), indium gallium zinc oxide (IGZO), or the like, but is not limited thereto.

Also, a connection line pattern 285 may be provided in the non-display area NA. For example, the connection line pattern 285 may be disposed in a direction crossing the gate line 116. For example, the connection line pattern 285 may be disposed in the non-display area NA between the display area AA and the gate pad GP in a first direction crossing the gate line 116. For example, the connection line pattern 285 may be disposed along the data line 117 in the longitudinal direction (in parallel) from the first gate line 116 to the last gate line 116.

The connection line pattern 285 may be made of the same transparent metal oxide as the semiconductor layer 124. The transparent metal oxide may be, for example, indium tin oxide (ITO), indium zinc oxide (IZO), indium gallium zinc oxide (IGZO), or the like, but is not limited thereto.

Thereafter, referring to FIG. 9B and FIG. 10B, the gate insulating layer 115a may be provided on the semiconductor layer 124 and the connection line pattern 285.

Then, the first contact hole 270a exposing a part of the connection line pattern 285 may be formed by selectively removing a portion of the gate insulating layer 115a.

Herein, the first contact hole 270a may be located in the non-display area NA adjacent to the display area AA, but is not limited thereto. For example, the first contact hole 270a may be located in the non-display area NA between the display area AA and the gate pad GP.

Then, referring to FIG. 9C and FIG. 10C, the gate electrode 121 and the gate line 116 may be provided on the gate insulating layer 115a.

For example, the gate line 116 may extend to the pad area PA of the non-display area NA in the second direction crossing the connection line pattern 285.

Also, the gate pad GP may be provided on the gate insulating layer 115a in the non-display area NA. For example, the gate pad GP may be provided at one end of each gate line 116 extending to the pad area PA.

In the second exemplary embodiment of the present disclosure, the gate line 116 may be connected to the connection line pattern 285 through the first contact hole 270a. Therefore, all of the gate lines 116 may be connected to each other by the connection line pattern 285. Also, even when static electricity is generated in a subsequent process, static electricity can be dispersed through the connected gate lines 116.

Thereafter, referring to FIG. 9D and FIG. 10D, the interlayer insulating layer 115b may be provided on the gate electrode 121, the gate line 116, and the gate pad GP.

Then, the second contact hole 270b exposing a part of the connection line pattern 285 may be formed by selectively removing a portion of the interlayer insulating layer 115b. The second contact hole 270b may be located in the non-display area NA adjacent to the display area AA, but is not limited thereto. Further, for example, the second contact hole 270b may be located in the non-display area NA between the display area AA and the gate pad GP. Furthermore, for example, the second contact hole 270b may be located on the connection line pattern 285 between the gate lines 116.

Thereafter, referring to FIG. 9E, FIG. 9F, and FIG. 10E, the source electrode 122, the drain electrode 123, and the data line 117 may be provided on the interlayer insulating layer 115b.

Also, the data pad DP may be disposed on the interlayer insulating layer 115b in the non-display area NA. For example, the data pad DP may be provided at one end of each data line 117 extending to the pad area PA.

Then, the protection layer 115f may be provided.

Further, the planarization layer 115 may be provided on the protection layer 115f.

The planarization layer 115 may extend to the non-display area NA excluding the pad area PA.

Thereafter, in the second exemplary embodiment of the present disclosure, the third contact hole 270c exposing a part of the protection layer 115f may be formed by selectively removing a portion of the planarization layer 115. For example, the third contact hole 270c may be located on the second contact hole 270b. For example, the third contact hole 270c may be located on the connection line pattern 285 between neighboring gate lines 116.

Then, the fourth contact hole 270d exposing a part of the connection line pattern 285 may be formed by selectively removing a portion of the protection layer 115f exposed by the third contact hole 270c. For example, the fourth contact hole 270d may be located on the second contact hole 270b. Thus, for example, the fourth contact hole 270d may expose an upper surface of the connection line pattern 285 between neighboring gate lines 116.

Herein, the third contact hole 270c and the fourth contact hole 270d may be sequentially formed, but the present disclosure is not limited thereto. The third contact hole 270c and the fourth contact hole 270d may be simultaneously formed.

Thereafter, referring to FIG. 9G, FIG. 10F, and FIG. 10G, the anode 131 may be provided on the second planarization layer 115d.

In the bottom emission method, the anode 131 may be made of a transparent conductive material, such as indium tin oxide (ITO), indium zinc oxide (IZO), indium gallium zinc oxide (IGZO), or the like.

The gate pad terminal GPT and the data pad terminal DPT may be provided on the second planarization layer 115d in the non-display area NA. For example, the gate pad terminal GPT may be electrically connected to the gate pad GP through the gate pad contact hole GPH, and the data pad terminal DPT may be connected to the data pad DP through the data pad contact hole DPH.

Herein, in the second exemplary embodiment of the present disclosure, a portion of the connection line pattern 285 exposed by the second, third and fourth contact holes 270b, 270c and 270d may be removed through the same etching process when the anode 131 is formed (patterned). Therefore, the connection line pattern 285 between neighboring gate lines 116 may be disconnected to form the connection line 280.

Then, bank 115e may be provided on the anode 131 and the second planarization layer 115d.

The bank 115e may extend to a part of the non-display area NA excluding the pad area PA, and may fill in a space between the connection lines 280 disconnected from each other.

Meanwhile, according to the present disclosure, a first connection line connecting gate lines to each other and a second connection line connecting the first connection lines are provided. Thus, it is possible to disperse static electricity. Details thereof will be described with reference to the accompanying drawings.

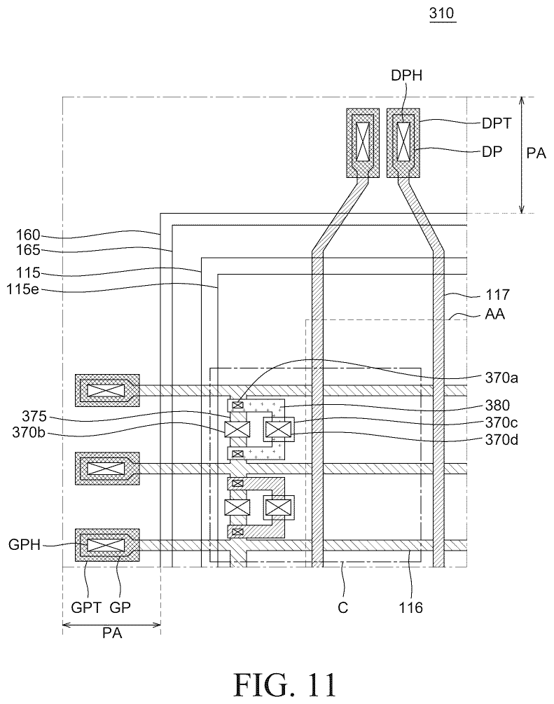

FIG. 11 is a plan view of a part of a display panel according to a third exemplary embodiment of the present disclosure.

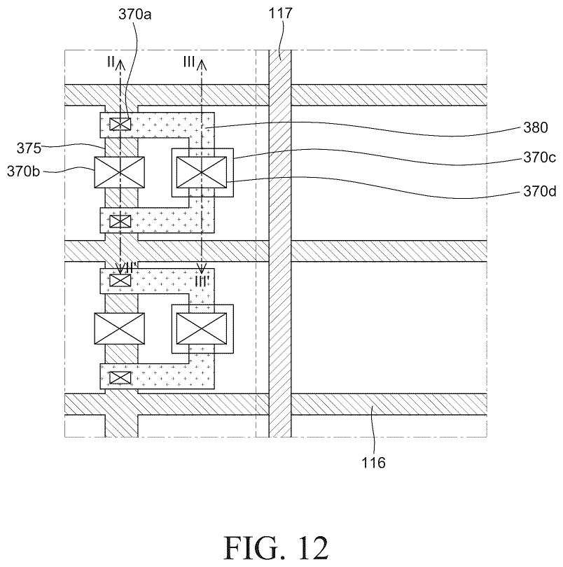

FIG. 12 is an enlarged view of an area C of FIG. 11 according to an exemplary embodiment of the present disclosure.

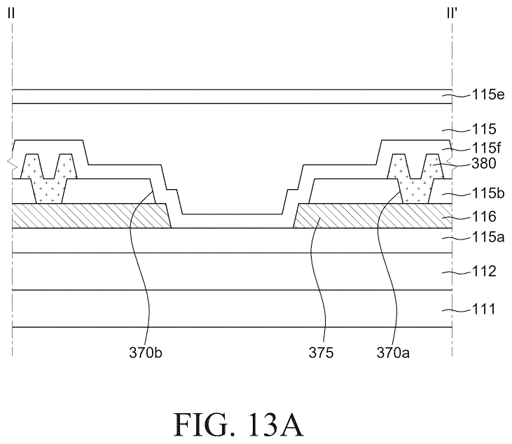

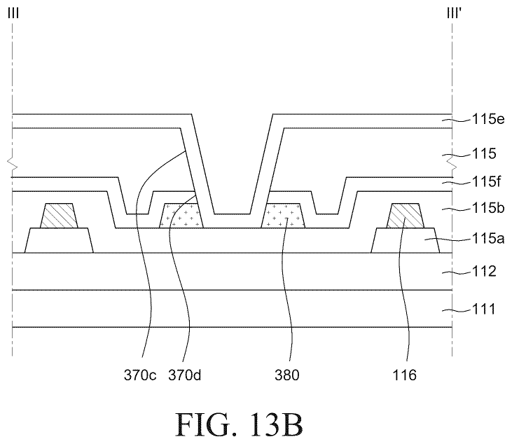

FIG. 13A is a cross-sectional view taken along a line II-II′ of FIG. 12 according to an exemplary embodiment of the present disclosure.

FIG. 13B is a cross-sectional view taken along a line III-III′ of FIG. 12 according to an exemplary embodiment of the present disclosure.

A display panel 310 according to the third exemplary embodiment of FIG. 11 through FIG. 13A and FIG. 13B is substantially the same as the second exemplary embodiment of FIG. 6 and FIG. 8 except that connection lines 375 and 380 are composed of a first connection line 375 connecting the gate lines 116 to each other and a second connection line 380 connecting the first connection lines 375. Therefore, redundant description thereof will be omitted. The same components will be denoted by the same reference numerals. Hereinafter, description of the same reference numerals may refer to FIG. 1 through FIG. 8.

Referring to FIG. 11 through FIG. 13A and FIG. 13B, the substrate 111 may be divided into the display area AA and the non-display area NA outside the display area AA.

The thin film transistor 120 and the light emitting element 130 may be disposed in the display area AA of the substrate 111.

The non-display area NA of the substrate 111 may include the pad area PA.

The gate pad GP and the data pad DP may be disposed in the pad area PA.

The buffer layer 112 may be disposed on the substrate 111.

The semiconductor layer 124 may be disposed on the buffer layer 112.

The gate insulating layer 115a may be disposed on the semiconductor layer 124.

The gate electrode 121 and the gate line 116 may be disposed on the gate insulating layer 115a. For example, the gate line 116 may extend to the pad area PA of the non-display area NA.

Also, the gate pad GP may be disposed on the gate insulating layer 115a in the non-display area NA. For example, the gate pad GP may be provided at one end of each gate line 116 extending to the pad area PA.

In the third exemplary embodiment of the present disclosure, a first connection line 375 may be disposed on the gate insulating layer 115a in a direction crossing the gate line 116.

For example, the first connection line 375 may be disposed along the data line 117 in the longitudinal direction (in parallel) from the first gate line 116 to the last gate line 116. Therefore, all of the gate lines 116 may be connected to each other by the first connection line 375. Also, even when static electricity is generated in a subsequent data line process, static electricity can be dispersed through the connected gate lines 116.

Further, the interlayer insulating layer 115b may be disposed on the gate electrode 121, the gate line 116, the gate pad GP, and the first connection line 375.

In the third exemplary embodiment of the present disclosure, a first contact hole 370a exposing a part of the first connection line 375 may be formed by selectively removing a portion of the interlayer insulating layer 115b. The first contact hole 370a may be located in the non-display area NA adjacent to the display area AA, but is not limited thereto. For example, the first contact hole 370a may be located in the non-display area NA between the display area AA and the gate pad GP. For example, the first contact hole 370a may be located on the first connection line 375 between neighboring gate lines 116. For example, the first contact hole 370a may be disposed on both sides of the first connection line 375 between neighboring gate lines 116.

Also, in the third exemplary embodiment of the present disclosure, a second contact hole 370b exposing a part of the first connection line 375 may be formed by selectively removing another portion of the interlayer insulating layer 115b. The second contact hole 370b may be located in the non-display area NA adjacent to the display area AA, but is not limited thereto. For example, the second contact hole 370b may be located in the non-display area NA between the display area AA and the gate pad GP. For example, the second contact hole 370b may be located on the first connection line 375 between the gate lines 116. For example, the second contact hole 370b may be disposed between the first contact holes 370a on both sides between the neighboring gate lines 116.

Further, for example, the second contact hole 370b may have a sufficient lateral width to expose another part of the first connection line 375. Thus, the first connection line 375 can be reliably disconnected through a process of disconnecting the first connection line 375 to be described below.

The source electrode 122, the drain electrode 123, and the data line 117 may be disposed on the interlayer insulating layer 115b.

The data pad DP may be disposed on the interlayer insulating layer 115b in the non-display area NA. For example, the data pad DP may be provided at one end of each data line 117 extending to the pad area PA.

In the third exemplary embodiment of the present disclosure, a second connection line 380 connecting both sides of the first connection line 375 may be disposed on the interlayer insulating layer 115b. For example, the second connection line 380 may be electrically connected to both sides of the first connection line 375 through the first contact holes 370a on both sides. For example, the second connection line 380 in the non-display area NA may be made of the same material on the same layer as the data line 117 in the display area AA, but is not limited thereto.

In the third exemplary embodiment of the present disclosure, another portion of the first connection line 375 exposed by the second contact hole 370b may be removed through an etching process when the data line 117 is formed (patterned). Therefore, the first connection line 375 between neighboring gate lines 116 may be disconnected.

For example, the second connection line 380 may bypass and connect the disconnected first connection line 375.

The protection layer 115f may be disposed on the thin film transistor 120 configured as described above.

Further, the planarization layer 115 may be provided on the protection layer 115f.

The planarization layer 115 may be an overcoating layer.

The planarization layer 115 may extend to the non-display area NA excluding the pad area PA.

The light emitting element 130 composed of the anode 131, the organic layer 132, and the cathode 133 may be disposed on the planarization layer 115.

Herein, in the third exemplary embodiment of the present disclosure, a third contact hole 370c exposing a part of the protection layer 115f may be formed by selectively removing a portion of the planarization layer 115. For example, the third contact hole 370c may be located on the second connection line 380 located on the side of the first connection line 375. For example, the third contact hole 370c may be located on the second connection line 380 between neighboring gate lines 116. For example, the third contact hole 370c may have a sufficient lateral width to expose a part of the second connection line 380.

In the third exemplary embodiment of the present disclosure, a fourth contact hole 370d exposing a part of the second connection line 380 may be formed by selectively removing a portion of the protection layer 115f exposed by the third contact hole 370c. For example, the fourth contact hole 370d may expose an upper surface of the second connection line 380 between neighboring gate lines 116. For example, the fourth contact hole 370d may have a sufficient lateral width to expose a part of the second connection line 380. Thus, the second connection line 380 can be reliably disconnected through a process of disconnecting the second connection line 380 to be described below.

For example, the third contact hole 370c may have a greater lateral width than the fourth contact hole 370d, but is not limited thereto.

The anode 131 may be disposed on the planarization layer 115.

The gate pad terminal GPT and the data pad terminal DPT may be disposed on the planarization layer 115 in the non-display area NA. For example, the gate pad terminal GPT may be electrically connected to the gate pad GP through the gate pad contact hole GPH, and the data pad terminal DPT may be connected to the data pad DP through the data pad contact hole DPH.

In the third exemplary embodiment of the present disclosure, a portion of the second connection line 380 exposed by the fourth contact hole 370d may be removed through an additional etching process after the anode 131 is formed (patterned). Therefore, the second connection line 380 between neighboring gate lines 116 may be disconnected.

The bank 115e may be disposed on the anode 131 and the planarization layer 115.

The bank 115e may extend to a part of the non-display area NA excluding the pad area PA, but is not limited thereto.

In the third exemplary embodiment of the present disclosure, the first connection line 375 connecting the gate lines 116 to each other and the second connection line 380 connecting the first connection lines 375 are provided to disperse static electricity. Thus, it is possible to effectively disperse static electricity generated during a process from the formation of the gate line 116 to the formation of the anode 131. Therefore, it is possible to improve the reliability of the display device.

Hereinafter, a process of manufacturing the display device according to the third exemplary embodiment of the present disclosure will be described in detail with reference to the accompanying drawing.

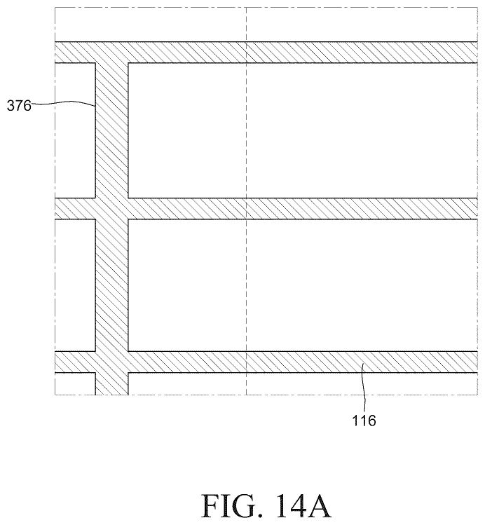

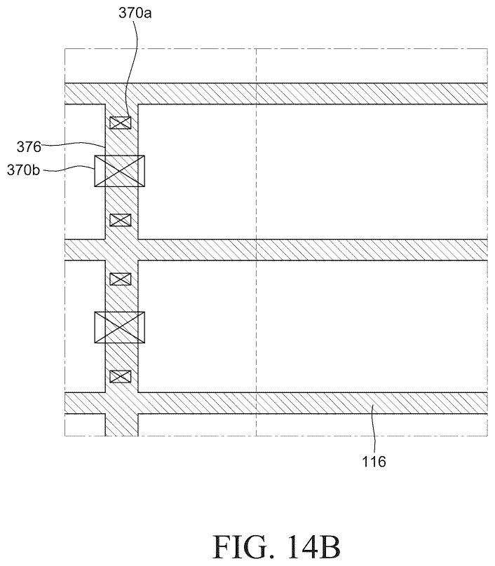

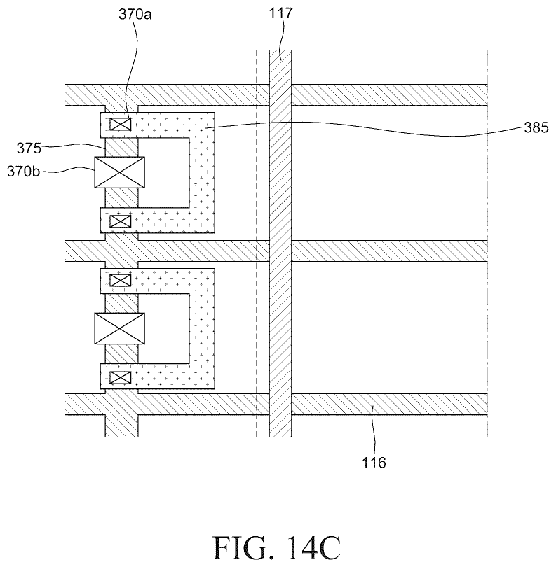

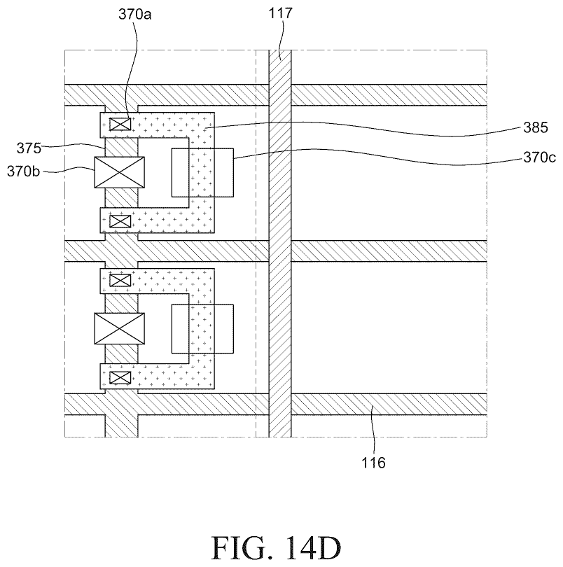

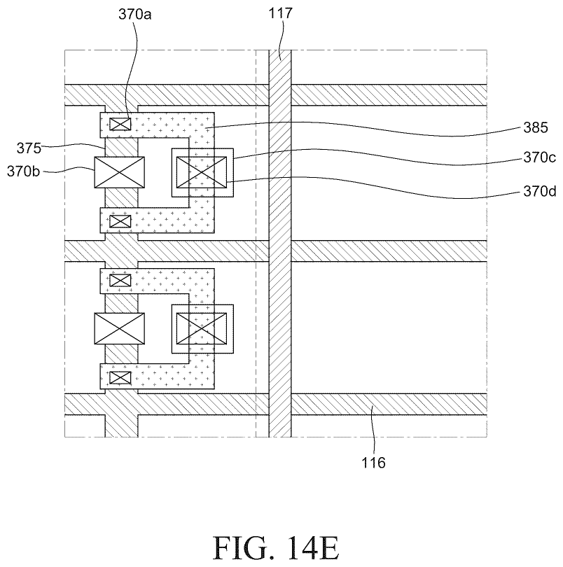

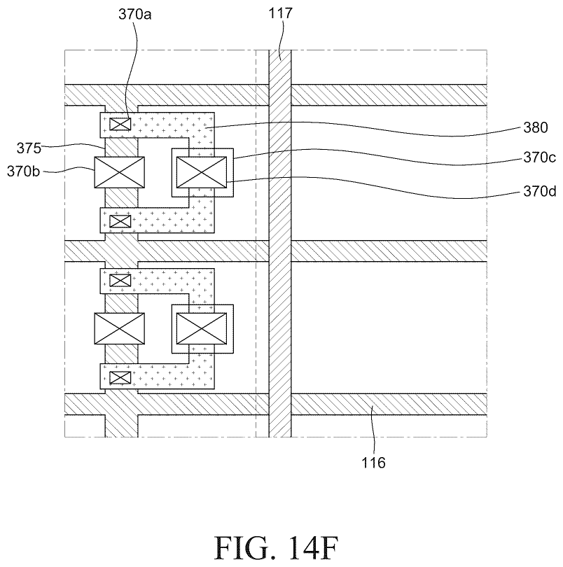

FIG. 14A through FIG. 14F are diagrams illustrating a process of manufacturing the display panel according to the third exemplary embodiment of the present disclosure of FIG. 12.

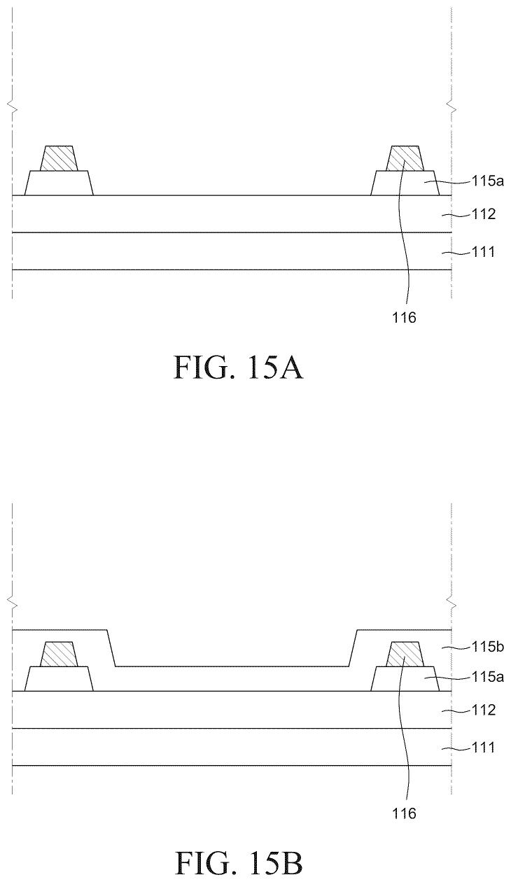

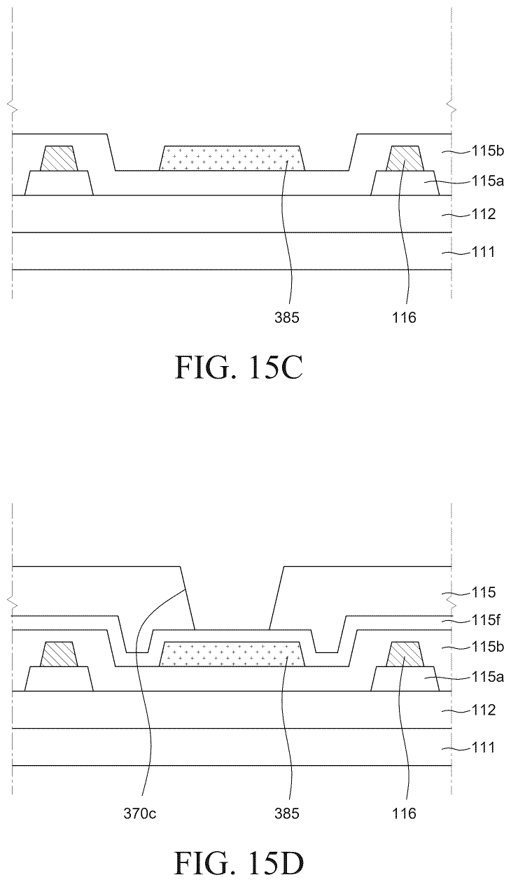

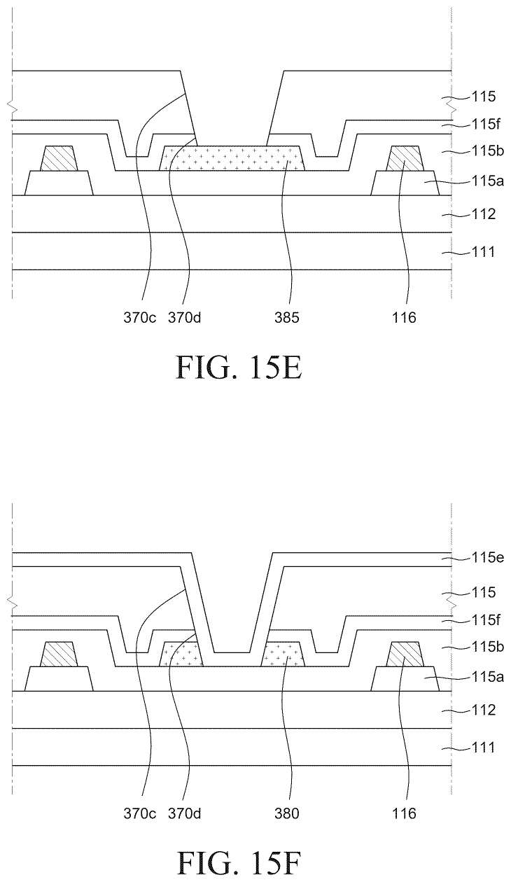

FIG. 15A through FIG. 15F are diagrams sequentially illustrating a process of manufacturing the display panel according to the third exemplary embodiment of the present disclosure of FIG. 13B.

FIG. 14A through FIG. 14F and FIG. 15A through FIG. 15F illustrate an example of the process of manufacturing the display panel according to the third exemplary embodiment of the present disclosure. The same components will be denoted by the same reference numerals. Hereinafter, description of the same reference numerals may refer to FIG. 1 through FIG. 8.

Referring to FIG. 14A and FIG. 15A, the buffer layer 112 may be disposed on the substrate 111 which is divided into the display area AA and the non-display area NA.

Then, the semiconductor layer 124 may be provided on the buffer layer 112.

Thereafter, the gate insulating layer 115a may be provided on the semiconductor layer 124.

The gate electrode 121 and the gate line 116 may be disposed on the gate insulating layer 115a. For example, the gate line 116 may extend to the pad area PA of the non-display area NA.

Also, the gate pad GP may be provided on the gate insulating layer 115a in the non-display area NA. For example, the gate pad GP may be provided at one end of each gate line 116 extending to the pad area PA.

In the third exemplary embodiment of the present disclosure, a first connection line pattern 376 may be provided on the gate insulating layer 115a in a direction crossing the gate line 116.

For example, the first connection line pattern 376 may be disposed along the data line 117 in the longitudinal direction (in parallel) from the first gate line 116 to the last gate line 116. Therefore, all of the gate lines 116 may be connected to each other by the first connection line pattern 376. Also, even when static electricity is generated in a subsequent data line process, static electricity can be dispersed through the connected gate lines 116.

Then, referring to FIG. 14B and FIG. 15B, the interlayer insulating layer 115b may be provided on the gate electrode 121, the gate line 116, the gate pad GP, and the first connection line pattern 376.

Thereafter, the first contact hole 370a exposing a part of the first connection line pattern 376 may be formed by selectively removing a portion of the interlayer insulating layer 115b. The first contact hole 370a may be located in the non-display area NA adjacent to the display area AA, but is not limited thereto. For example, the first contact hole 370a may be located in the non-display area NA between the display area AA and the gate pad GP. For example, the first contact hole 370a may be located on the first connection line pattern 376 between neighboring gate lines 116. For example, the first contact hole 370a may be provided on both sides of the first connection line pattern 376 between neighboring gate lines 116.

Also, the second contact hole 370b exposing another part of the first connection line pattern 376 may be formed by selectively removing another portion of the interlayer insulating layer 115b. The second contact hole 370b may be located in the non-display area NA adjacent to the display area AA, but is not limited thereto. For example, the second contact hole 370b may be located in the non-display area NA between the display area AA and the gate pad GP. For example, the second contact hole 370b may be located on the first connection line pattern 376 between the neighboring gate lines 116. For example, the second contact hole 370b may be provided between first contact holes 370a on both sides between neighboring gate lines 116. For example, the second contact hole 370b may have a sufficient lateral width to expose another part of the first connection line pattern 376.

Then, referring to FIG. 14C and FIG. 15C, the source electrode 122, the drain electrode 123, and the data line 117 may be provided on the interlayer insulating layer 115b.

The data pad DP may be disposed on the interlayer insulating layer 115b in the non-display area NA. For example, the data pad DP may be provided at one end of each data line 117 extending to the pad area PA.

A second connection line pattern 385 connecting both sides of the first connection line pattern 376 may be provided on the interlayer insulating layer 115b in the non-display area NA. For example, the second connection line pattern 385 may be electrically connected to both sides of the first connection line pattern 376 through the first contact holes 370a on both sides. For example, the second connection line pattern 385 may be provided on the same layer at the same time as the data line 117, but is not limited thereto.

In the third exemplary embodiment of the present disclosure, another portion of the first connection line pattern 376 exposed by the second contact hole 370b may be removed through an etching process when the data line 117 is formed (patterned). Therefore, the first connection line pattern 376 between neighboring gate lines 116 may be disconnected to form the first connection line 375.

For example, the second connection line pattern 385 may bypass and connect the disconnected first connection line 375.

Then, referring to FIG. 14D and FIG. 15D, the protection layer 115f may be provided.

Also, the planarization layer 115 may be provided on the protection layer 115f.

The planarization layer 115 may extend to the non-display area NA excluding the pad area PA.

Thereafter, in the third exemplary embodiment of the present disclosure, the third contact hole 370c exposing a part of the protection layer 115f may be formed by selectively removing a portion of the planarization layer 115. For example, the third contact hole 370c may be located on the second connection line pattern 385 located on the side of the first connection line 375. For example, the third contact hole 370c may be located on the second connection line pattern 385 between neighboring gate lines 116. For example, the third contact hole 370c may have a sufficient lateral width to expose a part of the second connection line pattern 385.

Then, referring to FIG. 14E and FIG. 15E, the fourth contact hole 370d exposing a part of the second connection line pattern 385 may be formed by selectively removing a portion of the protection layer 115f exposed by the third contact hole 370c. For example, the fourth contact hole 370d may expose an upper surface of the second connection line pattern 385 between neighboring gate lines 116. For example, the fourth contact hole 370d may have a sufficient lateral width to expose a part of the second connection line pattern 385.

For example, the third contact hole 370c may have a greater lateral width than the fourth contact hole 370d, but is not limited thereto.

Herein, the third contact hole 370c and the fourth contact hole 370d may be sequentially formed, but the present disclosure is not limited thereto. The third contact hole 370c and the fourth contact hole 370d may be simultaneously formed.

Thereafter, referring to FIG. 14F and FIG. 15F, the anode 131 may be provided on the planarization layer 115.

The gate pad terminal GPT and the data pad terminal DPT may be provided on the planarization layer 115 in the non-display area NA. For example, the gate pad terminal GPT may be electrically connected to the gate pad GP through the gate pad contact hole GPH, and the data pad terminal DPT may be connected to the data pad DP through the data pad contact hole DPH.

In the third exemplary embodiment of the present disclosure, a portion of the second connection line pattern 385 exposed by the fourth contact hole 370d may be removed through an additional etching process after the anode 131 is formed (patterned). Therefore, the second connection line pattern 385 between neighboring gate lines 116 may be disconnected to form the second connection line 380.

Then, the bank 115e may be provided on the anode 131 and the planarization layer 115.

The bank 115e may extend to a part of the non-display area NA excluding the pad area PA, and may fill in a space between the second connection lines 380 disconnected from each other.

Meanwhile, according to the present disclosure, a connection line connecting gate lines to each other is provided. Thus, it is possible to disperse static electricity. Details thereof will be described with reference to the accompanying drawings.

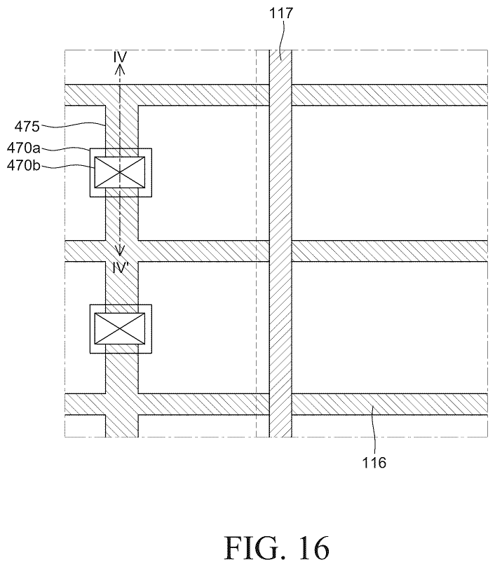

FIG. 16 is a plan view of a part of a display panel according to a fourth exemplary embodiment of the present disclosure.

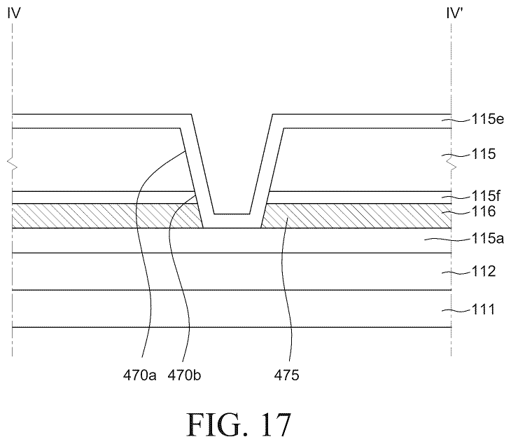

FIG. 17 is a cross-sectional view taken along a line IV-IV′ of FIG. 16 according to an exemplary embodiment of the present disclosure.

A display panel 410 according to the fourth exemplary embodiment of FIG. 16 and FIG. 17 is substantially the same as the third exemplary embodiment of FIG. 11 through FIG. 13A and FIG. 13B except that the display panel 410 includes one connection line 475. Therefore, redundant description thereof will be omitted. The same components will be denoted by the same reference numerals. Hereinafter, description of the same reference numerals may refer to FIG. 1 through FIG. 13A and FIG. 13B.

Referring to FIG. 16 and FIG. 17, the connection line 475 may be disposed on the gate insulating layer 115a in the non-display area NA in a direction crossing the gate line 116.

For example, the connection line 475 may be disposed along the data line 117 in the longitudinal direction (in parallel) from the first gate line 116 to the last gate line 116.

Meanwhile, in the fourth exemplary embodiment of the present disclosure, a first contact hole 470a exposing a part of the protection layer 115f may be formed by selectively removing a portion of the planarization layer 115. Herein, for example, the first contact hole 470a may be located on the connection line 475 between neighboring gate lines 116. Also, for example, the first contact hole 470a may have a sufficient lateral width to expose a part of the connection line 475. Further, in the fourth exemplary embodiment of the present disclosure, a second contact hole 470b exposing a part of the connection line 475 may be formed by selectively removing a portion of the protection layer 115f exposed by the first contact hole 470a. For example, the second contact hole 470b may expose an upper surface of the connection line 475 between the neighboring gate lines 116. For example, the second contact hole 470b may have a sufficient lateral width to expose a part of the connection line 475.

In the fourth exemplary embodiment of the present disclosure, a portion of the connection line 475 exposed by the second contact hole 475b may be removed through an additional etching process after the anode 131 is formed (patterned). Therefore, the connection line 475 between neighboring gate lines 116 may be disconnected.

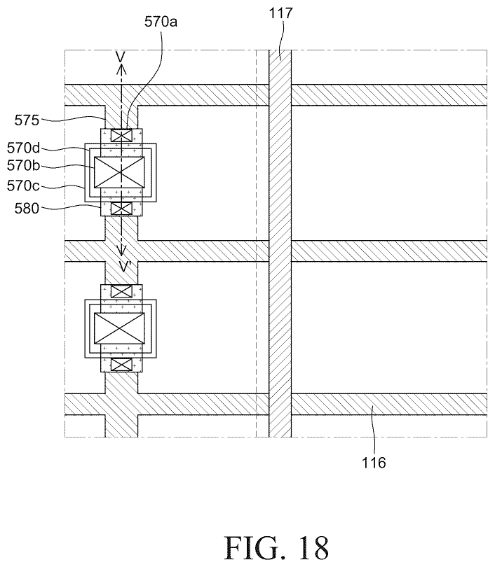

FIG. 18 is a plan view of a part of a display panel according to a fifth exemplary embodiment of the present disclosure.

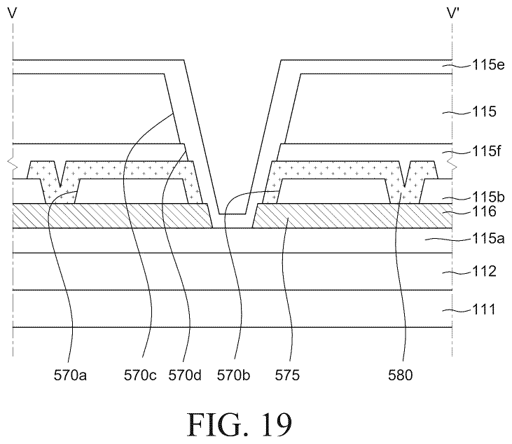

FIG. 19 is a cross-sectional view taken along a line V-V′ of FIG. 18 according to an exemplary embodiment of the present disclosure.

A display panel 510 according to the fifth exemplary embodiment of FIG. 18 and FIG. 19 is substantially the same as the fourth exemplary embodiment of FIG. 16 and FIG. 17 except that a second connection line 580 is disposed on a first connection line 575. Therefore, redundant description thereof will be omitted. The same components will be denoted by the same reference numerals. Hereinafter, description of the same reference numerals may refer to FIG. 1 through FIG. 7.

Referring to FIG. 18 and FIG. 19, the first connection line 575 may be disposed on the gate insulating layer 115a in the non-display area NA in a direction crossing the gate line 116. For example, the first connection line 575 may be disposed along the data line 117 in the longitudinal direction (in parallel) from the first gate line 116 to the last gate line 116.

In the fifth exemplary embodiment of the present disclosure, the second connection line 580 having an island shape is further disposed on the first connection line 575.

Specifically, for example, the interlayer insulating layer 115b may be disposed on the first connection line 575.

In the fifth exemplary embodiment of the present disclosure, a first contact hole 570a exposing a part of the first connection line 575 may be formed by selectively removing a portion of the interlayer insulating layer 115b. For example, the first contact hole 570a may be located on the first connection line 575 between neighboring gate lines 116. For example, the first contact hole 570a may be disposed on both sides of the first connection line 575 between neighboring gate lines 116.

Also, in the fifth exemplary embodiment of the present disclosure, a second contact hole 570b exposing a part of the first connection line 575 may be formed by selectively removing another portion of the interlayer insulating layer 115b. For example, the second contact hole 570b may be located on the first connection line 575 between neighboring gate lines 116. For example, the second contact hole 570b may be disposed between the first contact holes 570a on both sides between the neighboring gate lines 116. For example, the second contact hole 570b may have a sufficient lateral width to expose a part of the first connection line 575.

In the fifth exemplary embodiment of the present disclosure, the second connection line 580 electrically connected to the first connection line 575 through the first contact hole 570a may be disposed on the interlayer insulating layer 115b. For example, the second connection line 580 may be electrically connected to the first connection line 575 through the first contact holes 570a on both sides.

Further, in the fifth exemplary embodiment of the present disclosure, a third contact hole 570c exposing a part of the protection layer 115f may be formed by selectively removing a portion of the planarization layer 115. For example, the third contact hole 570c may be located on the second connection line 580 between neighboring gate lines 116. For example, the third contact hole 570c may have a sufficient lateral width to expose a part of the second connection line 580. For example, the third contact hole 570c may be located on the second contact hole 570b.

In the fifth exemplary embodiment of the present disclosure, a fourth contact hole 570d exposing a part of the second connection line 580 may be formed by selectively removing a portion of the protection layer 115f exposed by the third contact hole 570c. For example, the fourth contact hole 570d may expose an upper surface of the second connection line 580 between neighboring gate lines 116. For example, the fourth contact hole 570d may have a sufficient lateral width to expose a part of the second connection line 580. For example, the fourth contact hole 570d may be located on the second contact hole 570b and the third contact hole 570c.

In the fifth exemplary embodiment of the present disclosure, a portion of the second connection line 580 exposed by the fourth contact hole 570d and a portion of the underlying first connection line 575 may be removed through an additional etching process after the anode 131 is formed (patterned). Therefore, each of the first connection line 575 and the second connection line 580 between neighboring gate lines 116 may be disconnected.

Meanwhile, the first to fifth exemplary embodiments of the present disclosure can be applied to disperse static electricity in a data line. An example where the second exemplary embodiment is applied to the data line will be described in detail with reference to the accompanying drawings.

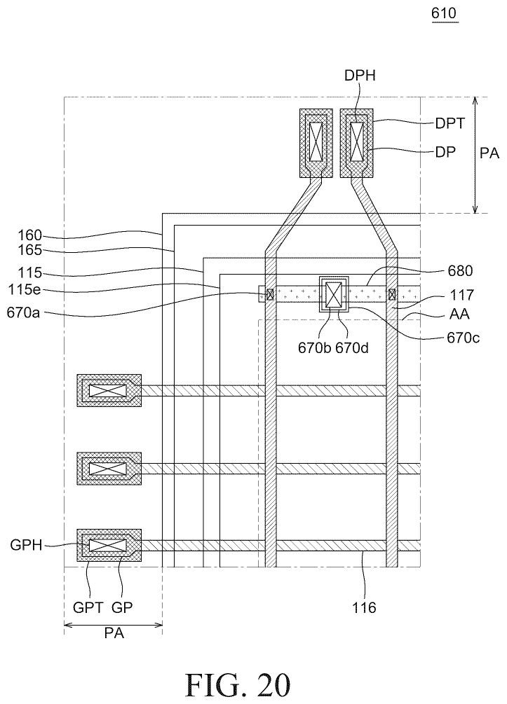

FIG. 20 is a plan view of a part of a display panel according to a sixth exemplary embodiment of the present disclosure.

A display panel 610 according to the sixth exemplary embodiment of FIG. 20 is substantially the same as the second exemplary embodiment of FIG. 6 through FIG. 8 except that a connection line 680 is applied to the data line 117. Therefore, redundant description thereof will be omitted. The same components will be denoted by the same reference numerals. Hereinafter, description of the same reference numerals may refer to FIG. 1 through FIG. 8.

Referring to FIG. 20, the substrate 111 may be divided into the display area AA and the non-display area NA outside the display area AA.

The non-display area NA of the substrate 111 may include the pad area PA.

The gate pad GP and the data pad DP may be disposed in the pad area PA.

The semiconductor layer 124 may be disposed on the buffer layer 112.

The semiconductor layer 124 may be made of an oxide semiconductor.

For example, the semiconductor layer 124 may be made of a transparent metal oxide, such as indium tin oxide (ITO), indium zinc oxide (IZO), indium gallium zinc oxide (IGZO), or the like, but is not limited thereto.

Also, the connection line 680 may be disposed in the non-display area NA. For example, the connection line 680 may be disposed in a direction crossing the data line 117. Further, for example, the connection line 680 may be disposed in the non-display area NA between the display area AA and the gate pad GP in a second direction crossing the data line 117. For example, the connection line 680 may be disposed along the gate line 116 in a longitudinal direction (in parallel) from the first data line 117 to the last data line 117.

For example, the connection line 680 may be made of a transparent metal oxide, such as indium tin oxide (ITO), indium zinc oxide (IZO), indium gallium zinc oxide (IGZO), or the like, but is not limited thereto.

The gate insulating layer 115a may be disposed on the semiconductor layer 124 and the connection line 680.

In the sixth exemplary embodiment of the present disclosure, a first contact hole 670a exposing a part of the connection line 680 may be formed by selectively removing a portion of the gate insulating layer 115a. The first contact hole 670a may be located in the non-display area NA adjacent to the display area AA, but is not limited thereto. For example, the first contact hole 670a may be disposed in the non-display area NA between the display area AA and the gate pad GP.

The gate electrode 121 and the gate line 116 may be disposed on the gate insulating layer 115a.

Further, the interlayer insulating layer 115b may be disposed on the gate electrode 121, the gate line 116, and the gate pad GP.

In the sixth exemplary embodiment of the present disclosure, a second contact hole 670b exposing a part of the connection line 680 may be formed by selectively removing a portion of the interlayer insulating layer 115b. The second contact hole 670b may be located in the non-display area NA adjacent to the display area AA, but is not limited thereto. For example, the second contact hole 670b may be located in the non-display area NA between the display area AA and the gate pad GP. For example, the second contact hole 670b may be located on the connection line 680 between the data lines 117. For example, the second contact hole 670b may have a sufficient lateral width to expose a part of the connection line 680. Thus, the connection line 680 can be reliably disconnected through a process of disconnecting the connection line 680 to be described below.

The source electrode 122, the drain electrode 123, and the data line 117 may be disposed on the interlayer insulating layer 115b.

In the sixth exemplary embodiment of the present disclosure, the data line 117 may be electrically connected to the connection line 680 through the first contact hole 670a. Therefore, all of the data lines 117 may be connected to each other by the connection line 680. Also, even when static electricity is generated in a subsequent process, static electricity can be dispersed through the connected data lines 117.

The protection layer 115f may be disposed on the thin film transistor 120.

Also, the planarization layer 115 may be disposed on the protection layer 115f.

Herein, in the sixth exemplary embodiment of the present disclosure, a third contact hole 670c exposing a part of the protection layer 115f may be formed by selectively removing a portion of the planarization layer 115. For example, the third contact hole 670c may be located on the second contact hole 670b. For example, the third contact hole 670c may be located on the connection line 680 between neighboring data lines 117.

For example, the third contact hole 670c may have a greater lateral width than the second contact hole 670b.

In the sixth exemplary embodiment of the present disclosure, a fourth contact hole 670d exposing a part of the connection line 680 may be formed by selectively removing a portion of the protection layer 115f exposed by the third contact hole 670c. For example, the fourth contact hole 670d may be located on the second contact hole 670b. Thus, for example, the fourth contact hole 670d may expose an upper surface of the connection line 680 between neighboring data lines 117.

For example, the fourth contact hole 670d may have a greater lateral width than the second contact hole 670b.

The anode 131 may be disposed on the planarization layer 115.

In the bottom emission method, the anode 131 may be made of a transparent conductive material, such as indium tin oxide (ITO), indium zinc oxide (IZO), indium gallium zinc oxide (IGZO), or the like. However, the present disclosure is not limited thereto. The top emission method can also be applied.

In the sixth exemplary embodiment of the present disclosure, a portion of the connection line 680 exposed by the second, third and fourth contact holes 670b, 670c and 670d may be removed through the same etching process when the anode 131 is formed (patterned). Therefore, the connection line 680 between neighboring data lines 117 may be disconnected.

In the sixth exemplary embodiment of the present disclosure, the connection line 680 may be disposed on the same layer as the semiconductor layer 124 under the data line 117 to disperse static electricity. Thus, it is possible to disperse static electricity generated during a process from the formation of the data line 117 to the formation of the anode 131. Therefore, it is possible to improve the reliability of the display device.

Further, in the sixth exemplary embodiment of the present disclosure, the connection line 680 is made of a transparent metal oxide to minimize a reflectivity of the display panel. Therefore, low power consumption can be achieved.

Furthermore, in the sixth exemplary embodiment of the present disclosure, the connection line 680 is made of the same transparent metal oxide as the anode 131. Thus, the connection line 680 can be patterned when the anode 131 is formed. Therefore, the process can be simplified.

The exemplary embodiments of the present disclosure can also be described as follows:

According to an aspect of the present disclosure, there is provided a display device. The display device includes a substrate including a display area and a non-display area, a semiconductor layer disposed on the substrate in the display area, a connection line disposed on the substrate in the non-display area, a gate insulating layer disposed on the semiconductor layer and the connection line, a gate line disposed on the gate insulating layer and connected to the connection line, at least one insulating layer disposed on the gate line and a light emitting element disposed on the at least one insulating layer, the connection line may be made of a metal oxide and disposed on the same layer as the semiconductor layer, and the connection line between neighboring gate lines may be partially removed and thus disconnected.

The display device may further comprise a first contact hole which exposes a part of the connection line by removing a portion of the gate insulating layer, the first contact hole may be located between the non-display area between the display area and a gate pad.

The gate line may be connected to the connection line through the first contact hole.

The at least one insulating layer may include an interlayer insulating layer disposed on the gate line, and the display device may further include a second contact hole which may expose a part of the connection line by selectively removing a portion of the interlayer insulating layer.

The second contact hole may be located on the connection line between neighboring gate lines, and the exposed part of the connection line under the second contact hole may be removed.

The connection line may be disposed in a direction crossing the gate line.

The display device may further comprise a data line disposed on the gate line in a direction parallel to the connection line, the at least one insulating layer may include a protection layer and a planarization layer disposed on the data line.

The display device may further comprise a third contact hole which exposes a part of the protection layer by selectively removing a portion of the planarization layer, the third contact hole may be located on the second contact hole.

The display device may further comprise a fourth contact hole which may expose a part of the connection line by selectively removing a portion of the protection layer exposed by the third contact hole, the fourth contact hole may be located on the second contact hole.

The third contact hole may be located on the connection line between neighboring gate lines, and the fourth contact hole may expose an upper surface of the connection line between the neighboring gate lines.

The third contact hole and the fourth contact hole may have a greater lateral width than the second contact hole.

The light emitting element may include an anode, and the connection line may not be disconnected before the anode may be patterned, and in case the anode may be patterned, the part of the connection line exposed by the fourth contact hole may be also removed to disconnect the connection line between the neighboring gate lines.

According to another aspect of the present disclosure, there is provided a display device. The display device includes a substrate including a display area and a non-display area, a gate line disposed on the substrate, a first connection line disposed in a direction crossing the gate line and connected to the gate line, an interlayer insulating layer disposed on the gate line, a second connection line disposed on the interlayer insulating layer and connected to the first connection line, at least one insulating layer disposed on the second connection line and a light emitting element disposed on the at least one insulating layer, each of the first connection line and the second connection line between neighboring gate lines may be partially removed and thus disconnected.

The display device may further comprise a first contact hole which may expose a part of the first connection line by removing a portion of the interlayer insulating layer, the first contact hole may be located between the non-display area between the display area and a gate pad.

The first contact hole may be disposed on both sides of the first connection line between the neighboring gate lines, and the second connection line may be connected to the first connection line through the first contact holes on both sides.

The display device may further comprise a second contact hole which may expose another part of the first connection line by selectively removing another portion of the interlayer insulating layer.

The second contact hole may be located on the first connection line between the neighboring gate lines, and the second contact hole may be disposed between the first contact holes on both sides between the neighboring gate lines.

The display device may further comprise a data line disposed on the gate line in a direction parallel to the first connection line, the at least one insulating layer may include a protection layer and a planarization layer disposed on the data line.

The display device may further comprise a third contact hole which may expose a part of the protection layer by selectively removing a portion of the planarization layer, the third contact hole may be located on the second connection line located on of the side of the first connection line.

The display device may further comprise a fourth contact hole which may expose a part of the second connection line by selectively removing a portion of the protection layer exposed by the third contact hole, the fourth contact hole may expose an upper surface of the second connection line between the neighboring gate lines.

The first connection line may not be disconnected before the data line may be patterned, and in case the data line may be patterned, the other part of the first connection line exposed by the second contact hole may be also removed to disconnect the first connection line between the neighboring gate lines.

The light emitting element may include an anode, and the second connection line may not be disconnected before the anode may be patterned, and in case the anode may be patterned, the part of the second connection line exposed by the fourth contact hole may be also removed to disconnect the second connection line between the neighboring gate lines. Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including a display area and a non-display area;
a semiconductor layer on the substrate in the display area;
a connection line on the substrate in the non-display area;
a gate insulating layer on the semiconductor layer and the connection line;
a gate line on the gate insulating layer, the gate line connected to the connection line;
at least one insulating layer on the gate line; and
a light emitting element on the at least one insulating layer;
wherein the connection line includes a metal oxide and is on a same layer as the semiconductor layer, and the connection line between neighboring gate lines is partially removed and disconnected.

2. The display device according to claim 1, further comprising:
a first contact hole that exposes a part of the connection line by removing a portion of the gate insulating layer,
wherein the first contact hole is between the non-display area between the display area and a gate pad.

3. The display device according to claim 2, wherein the gate line is connected to the connection line through the first contact hole.

4. The display device according to claim 1, wherein the at least one insulating layer includes an interlayer insulating layer on the gate line, and the display device further comprises a second contact hole that exposes a part of the connection line through a portion of the interlayer insulating layer.

5. The display device according to claim 4, wherein the second contact hole is on the connection line between the neighboring gate lines, and the exposed part of the connection line under the second contact hole is removed.

6. The display device according to claim 1, wherein the connection line is disposed in a direction crossing the gate line.

7. The display device according to claim 4, further comprising:
a data line on the gate line in a direction parallel to the connection line,
wherein the at least one insulating layer includes a protection layer and a planarization layer on the data line.

8. The display device according to claim 7, further comprising:
a third contact hole that exposes a part of the protection layer through a portion of the planarization layer, the third contact hole on the second contact hole.

9. The display device according to claim 8, further comprising:
a fourth contact hole that exposes a part of the connection line through a portion of the protection layer exposed by the third contact hole, the fourth contact hole on the second contact hole.

10. The display device according to claim 9, wherein the third contact hole is on the connection line between the neighboring gate lines, and the fourth contact hole exposes an upper surface of the connection line between the neighboring gate lines.

11. The display device according to claim 9, wherein the third contact hole and the fourth contact hole have a greater lateral width than the second contact hole.

12. The display device according to claim 10, wherein the light emitting element includes an anode, and the connection line is not disconnected before the anode is patterned, and
wherein in a case the anode is patterned, the part of the connection line exposed by the fourth contact hole is also removed to disconnect the connection line between the neighboring gate lines.

13. A display device, comprising:
a substrate including a display area and a non-display area;
a gate line on the substrate;
a first connection line disposed in a direction crossing the gate line, the first connection line connected to the gate line;
an interlayer insulating layer on the gate line;
a second connection line on the interlayer insulating layer, the second connection line connected to the first connection line;
at least one insulating layer on the second connection line; and
a light emitting element on the at least one insulating layer,
wherein each of the first connection line and the second connection line between neighboring gate lines is partially removed and disconnected.

14. The display device according to claim 13 further comprising:
a first contact hole that exposes a part of the first connection line through a portion of the interlayer insulating layer, the first contact hole between the non-display area between the display area and a gate pad.

15. The display device according to claim 14, wherein the first contact hole is on both sides of the first connection line between the neighboring gate lines, and the second connection line is connected to the first connection line through the first contact hole on both sides.

16. The display device according to claim 14, further comprising:
a second contact hole that exposes another part of the first connection line through another portion of the interlayer insulating layer.

17. The display device according to claim 16, wherein the second contact hole is on the first connection line between the neighboring gate lines, and the second contact hole is between the first contact hole on both sides of the first connection line between the neighboring gate lines.

18. The display device according to claim 17, further comprising:
a data line on the gate line in a direction parallel to the first connection line,
wherein the at least one insulating layer includes a protection layer and a planarization layer on the data line.

19. The display device according to claim 18, further comprising:
a third contact hole that exposes a part of the protection layer through a portion of the planarization layer, the third contact hole on the second connection line located on the side of the first connection line.

20. The display device according to claim 19, further comprising:
a fourth contact hole that exposes a part of the second connection line through a portion of the protection layer exposed by the third contact hole, the fourth contact hole exposing an upper surface of the second connection line between the neighboring gate lines.

21. The display device according to claim 20, wherein the first connection line is not disconnected before the data line is patterned, and wherein in a case the data line is patterned, another part of the first connection line exposed by the second contact hole is also removed to disconnect the first connection line between the neighboring gate lines.

22. The display device according to claim 20, wherein the light emitting element includes an anode, and the second connection line is not disconnected before the anode is patterned, and
wherein in a case the anode is patterned, the part of the second connection line exposed by the fourth contact hole is also removed to disconnect the second connection line between the neighboring gate lines.
